(19) United States
(12) Patent Application Publication
(10) Pub. No.: US 2026/0206441 A1
(43) Pub. Date: Jul. 16, 2026

(54) DISPLAY PANEL AND ELECTRONIC DEVICE INCLUDING THE SAME

(71) Applicant: Samsung Display Co., Ltd., Yongin-si (KR)

(72) Inventors: Dong Hee SHIN, Yongin-si (KR); Doyeong PARK, Yongin-si (KR); Yunmi KIM, Yongin-si (KR); Hyeongseok KIM, Yongin-si (KR)

(73) Assignee: Samsung Display Co., Ltd., Yongin-si (KR)

(21) Appl. No.: 19/399,917

(22) Filed: Nov. 25, 2025

(30) Foreign Application Priority Data
Jan. 10, 2025 (KR) 10-2025-0004399

(51) Int. Cl. H10K 59/131; H10K 59/121

(52) U.S. Cl. CPC H10K 59/131; H10K 59/1213

(57) ABSTRACT

A display panel is provided. The display panel includes: a first pixel configured to emit first light; a second pixel configured to emit second light; a third pixel configured to emit third light; a fourth pixel configured to emit fourth light; a first data line configured to provide a first data signal to the first pixel and the third pixel, respectively; and a second data line configured to provide a second data signal to the second pixel and the fourth pixel, respectively. A wavelength of the second light is greater than a wavelength of the third light and less than a wavelength of the first light. A wavelength of the fourth light is greater than the wavelength of the third light and less than the wavelength of the first light. The first pixel or the third pixel is between the second pixel and the fourth pixel.

### CROSS-REFERENCE TO RELATED APPLICATION

This application claims priority to Korean Patent Application No. 10-2025-0004399, filed on January 10, 2025, in the Korean Intellectual Property Office, the disclosure of which is incorporated by reference herein in its entirety.

### BACKGROUND

### Field

The present disclosure relates to a display panel and an electronic device including the same. Particularly, the present disclosure relates to a display panel having a minimized deviation in distance between a data line and a pixel circuit, and an electronic device including the same.

### Description of Related Art

A display panel includes a plurality of pixels, and each of the plurality of pixels may include a pixel circuit and a light-emitting diode. The pixel circuit may be formed through a deposition process for deposition of several layers of patterns. Due to an error in a deposition process, patterns may be deposited at undesired positions, and resulting in luminance deviation between pixels. Particularly, the less uniform distances between a data line and a pixel circuit are, the larger a luminance deviation due to the above is.

### SUMMARY

One or more embodiments provide a display panel minimized distance luminance deviation by disposing a data line on a pixel that does not receive a data signal from the data line, and an electronic device including the same.

According to an aspect of an embodiment, a display panel includes: a first pixel configured to emit first light; a second pixel configured to emit second light; a third pixel configured to emit third light; a fourth pixel configured to emit fourth light; a first data line configured to provide a first data signal to the first pixel and the third pixel, respectively; and a second data line configured to provide a second data signal to the second pixel and the fourth pixel, respectively. A wavelength of the second light is greater than a wavelength of the third light and less than a wavelength of the first light, and a wavelength of the fourth light is greater than the wavelength of the third light and less than the wavelength of the first light. The first pixel or the third pixel is between the second pixel and the fourth pixel.

The first pixel may include a first pixel circuit and a first light-emitting diode, the second pixel may include a second pixel circuit and a second light-emitting diode, the third pixel may include a third pixel circuit and a third light-emitting diode, the fourth pixel may include a fourth pixel circuit and a fourth light-emitting diode, the first data line may have at least a portion overlapping with the second pixel circuit, and the second data line may have at least a portion overlapping with the third pixel circuit.

The first pixel circuit may include: a first driving transistor connected to the first light-emitting diode; and a first switching transistor between the first data line and a control electrode of the first driving transistor. The second pixel circuit may include: a second driving transistor connected to the second light-emitting diode; and a second switching transistor between the second data line and a control electrode of the second driving transistor. The third pixel circuit may include: a third driving transistor connected to the third light-emitting diode; and a third switching transistor between the first data line and a control electrode of the third driving transistor. The fourth pixel circuit may include: a fourth driving transistor connected to the fourth light-emitting diode; and a fourth switching transistor between the second data line and a control electrode of the fourth driving transistor. The first switching transistor and the third switching transistor may be controlled by a first gate signal, and the second switching transistor and the fourth switching transistor may be controlled by a second gate signal.

The display panel may further include: a first gate line configured to provide the first gate signal; and a second gate line configured to provide the second gate signal.

The display panel may further include a reference voltage line configured to provide a reference voltage signal, the first pixel circuit may further include a first compensation transistor between the reference voltage line and the control electrode of the first driving transistor, the second pixel circuit may further include a second compensation transistor between the reference voltage line and the control electrode of the second driving transistor, the third pixel circuit may further include a third compensation transistor between the reference voltage line and the control electrode of the third driving transistor, and the fourth pixel circuit may further include a fourth compensation transistor between the reference voltage line and the control electrode of the fourth driving transistor.

The display panel may further include a third gate line configured to provide a third gate signal. Each of the first compensation transistor through the fourth compensation transistor may be controlled by the third gate signal.

The display panel may further include an initialization line configured to provide an initialization signal, the first pixel circuit may further include a first initialization transistor between the initialization line and the first light-emitting diode, the second pixel circuit may further include a second initialization transistor between the initialization line and the second light-emitting diode, the third pixel circuit may further include a third initialization transistor between the initialization line and the third light-emitting diode, and the fourth pixel circuit may further include a fourth initialization transistor between the initialization line and the fourth light-emitting diode.

The display panel may further include a fourth gate line configured to provide a fourth gate signal. Each of the first initialization transistor through the fourth initialization transistor may be controlled by the fourth gate signal.

The display panel may further include a first power line configured to provide a first power signal, the first pixel circuit may further include a first main light-emission control transistor between the first power line and the first driving transistor, the second pixel circuit may further include a second main light-emission control transistor between the first power line and the second driving transistor, the third pixel circuit may further include a third main light-emission control transistor between the first power line and the third driving transistor, and the fourth pixel circuit may further include a fourth main light-emission control transistor between the first power line and the fourth driving transistor.

The display panel may further include a fifth gate line configured to provide a fifth gate signal. Each of the first main light-emission control transistor through the fourth main light-emission control transistor may be controlled by the fifth gate signal.

The first pixel circuit may further include a first sub light-emission control transistor between the first driving transistor and the first light-emitting diode, the second pixel circuit may further include a second sub light-emission control transistor between the second driving transistor and the second light-emitting diode, the third pixel circuit may further include a third sub light-emission control transistor between the third driving transistor and the third light-emitting diode, and the fourth pixel circuit may further include a fourth sub light-emission control transistor between the fourth driving transistor and the fourth light-emitting diode.

The display panel may further include a sixth gate line configured to provide a sixth gate signal, and the first sub light-emission control transistor through the fourth sub light-emission control transistor may be controlled by the sixth gate signal.

The display panel may further include a second power line configured to provide a second power signal, and the second power line may be connected to each of the first light-emitting diode through the fourth light-emitting diode.

According to another aspect of an embodiment, an electronic device includes: a semiconductor pattern including a lower semiconductor pattern and an upper semiconductor pattern on different layers, wherein the lower semiconductor pattern includes a first lower semiconductor portion through a fourth lower semiconductor portion spaced apart from one another and sequentially provided along a first direction, wherein the upper semiconductor pattern includes a first upper semiconductor portion through a fourth upper semiconductor portion sequentially provided along the first direction, and wherein the third upper semiconductor portion extends from the second upper semiconductor portion; a gate pattern including a sub gate pattern and an upper gate pattern, wherein the sub gate pattern includes a first sub gate portion through a fourth sub gate portion overlapping with the first lower semiconductor portion through the fourth lower semiconductor portion, respectively, and wherein the upper gate pattern is above the upper semiconductor pattern and includes a first upper gate portion through a fourth upper gate portion overlapping with the first upper semiconductor portion through the fourth upper semiconductor portion, respectively; and an upper conductive pattern above the upper gate pattern and including a first upper conductive portion and a second upper conductive portion, each of the first upper conductive portion and the second upper conductive portion extending in a second direction intersecting with the first direction, wherein the first upper conductive portion overlaps with at least any one of the second lower semiconductor portion, the second sub gate portion, the second upper semiconductor portion, and the second upper gate portion, and wherein the second upper conductive portion overlaps with at least any one of the third lower semiconductor portion, the third sub gate portion, the third upper semiconductor portion, and the third upper gate portion, wherein the first upper conductive portion is configured to provide a first data signal to the first sub gate portion and the third sub gate portion, or to the first upper gate portion and the third upper gate portion, and wherein the second upper conductive portion is configured to provide a second data signal to the second sub gate portion and the fourth sub gate portion, or to the second upper gate portion and the fourth upper gate portion.

The electronic device may further include a lower conductive pattern between the upper gate pattern and the upper conductive pattern, the lower conductive pattern may include a first lower conductive portion and a second lower conductive portion spaced apart from each other, the upper semiconductor pattern may further include a fifth upper semiconductor portion through an eighth upper semiconductor portion spaced apart from the first upper semiconductor portion through the fourth upper semiconductor portion and sequentially provided along the first direction, the upper gate pattern may further include a fifth upper gate portion through an eighth upper gate portion overlapping with the fifth upper semiconductor portion through the eighth upper semiconductor portion, respectively, the first lower conductive portion may be configured to provide a first gate signal to the fifth upper gate portion and the seventh upper gate portion, respectively, and the second lower conductive portion may be configured to provide a second gate signal to the sixth upper gate portion and the eighth upper gate portion, respectively.

The lower conductive pattern may further include a third lower conductive portion, the upper semiconductor pattern may further include a ninth upper semiconductor portion through a twelfth upper semiconductor portion extending from the fifth upper semiconductor portion through the eighth upper semiconductor portion, respectively, the upper gate pattern may further include a ninth upper gate portion through a twelfth upper gate portion overlapping with the ninth upper semiconductor portion through the twelfth upper semiconductor portion, respectively, and the third lower conductive portion may be configured to provide a third gate signal to the ninth upper gate portion through the eleventh upper gate portion, respectively.

The upper semiconductor pattern may further include a thirteenth upper semiconductor portion through a sixteenth upper semiconductor portion spaced part from the first upper semiconductor portion through the twelfth upper semiconductor portion and sequentially provided along the first direction, the upper gate pattern may further include a thirteenth upper gate portion through the sixteenth upper gate portion overlapping with the thirteenth upper semiconductor portion through the sixteenth upper semiconductor portion, respectively, the fourteenth upper gate portion may extend from the thirteenth gate portion, the fifteenth upper gate portion may extend from the fourteenth upper gate portion, and the sixteenth upper gate portion may extend from the fifteenth upper gate portion, and the thirteenth upper gate portion through the sixteenth upper gate portion may be respectively provided with a fourth gate signal.

The lower semiconductor pattern may further include a fifth lower semiconductor portion through a twelfth lower semiconductor portion spaced apart from the first lower semiconductor portion through the fourth lower semiconductor portion, the sub gate pattern may further include a fifth sub gate portion through a twelfth sub gate portion overlapping with the fifth lower semiconductor portion through the twelfth lower semiconductor portion, the fifth sub gate portion through the eighth sub gate portion may be provided with a fifth gate signal, and the ninth sub gate portion through the twelfth sub gate portion may be provided with a sixth gate signal.

The upper conductive pattern may further include a third upper conductive portion configured to provide an initialization signal or a reference voltage signal, and a fourth upper conductive portion configured to provide a first power signal, the first upper conductive portion and the second upper conductive portion may be between the third upper conductive portion and the fourth upper conductive portion, the third upper conductive portion may be connected to the ninth upper semiconductor portion through the twelfth upper semiconductor portion or to the thirteenth upper semiconductor portion through the sixteenth upper semiconductor portion, and the fourth upper conductive portion may be connected to the fifth lower semiconductor portion through the eighth lower semiconductor portion, respectively.

According to another aspect of an embodiment, an electronic device includes a display panel, and the display panel includes: a first pixel configured to emit first light; a second pixel configured to emit second light; a third pixel configured to emit third light; a fourth pixel configured to emit fourth light; a first data line configured to provide a first data signal to the first pixel and the third pixel; and a second data line configured to provide a second data signal to the second pixel and the fourth pixel. A wavelength of the second light is greater than a wavelength of the third light and less than a wavelength of the first light, and a wavelength of the fourth light is greater than the wavelength of the third light and less than the wavelength of the first light. The first pixel or the third pixel is between the second pixel and the fourth pixel.

According to one embodiment of the present disclosure, an object of the present disclosure is to provide a display panel having the described distance deviation and the described luminance deviation minimized by disposing a data line on a pixel that does not receive a data signal from a data line, and an electronic device including the same.

### BRIEF DESCRIPTION OF DRAWINGS

The above and other features will be more apparent from the following description of embodiments, taken in conjunction with the accompanying drawings, in which:

FIG. 1A illustrates an exemplary block diagram of an electronic device according to one or more embodiments;

FIG. 1B is an exemplary illustration of an electronic device according to one or more embodiments;

FIG. 1C and FIG. 1D exemplarily illustrate an assembled perspective view and an exploded perspective view, respectively, of an electronic device according to one or more embodiments;

FIG. 2A is an exemplary plan view of a display panel according to one or more embodiments;

FIG. 2B is an exemplary block diagram of a display panel according to one or more embodiments;

FIGS. 2C, 2D and 2E are exemplary block diagrams of a pixel group among the plurality of pixels shown in FIG. 2B;

FIGS. 3A, 3B, 3C and 3D are exemplary equivalent circuit diagrams of a first pixel through a fourth pixel according to one or more embodiments;

FIG. 4 illustrates a portion of an exemplary cross-sectional view of a display panel according to one or more embodiments;

FIG. 5 is an exemplary illustration of a shape in which a semiconductor pattern, a gate pattern, and a conductive pattern overlap one another according to one or more embodiments;

FIG. 6 is a plan view of a lower semiconductor pattern according to one or more embodiments;

FIG. 7A is a plan view of a doping mask pattern according to one or more embodiments;

FIG. 7B is an exemplary illustration in which the shape shown in FIG. 7A is superimposed on FIG. 6;

FIG. 8A is a plan view of a sub gate pattern according to one or more embodiments;

FIG. 8B is an exemplary illustration in which the shape shown in FIG. 8A is superimposed on FIG. 6;

FIG. 9A is a plan view of a lower gate pattern according to one or more embodiments;

FIG. 9B is an exemplary illustration in which the shape shown in FIG. 9A is superimposed on FIG. 8B;

FIG. 10A is a plan view of an upper semiconductor pattern according to one or more embodiments;

FIG. 10B is an exemplary illustration in which the shape shown in FIG. 10A is superimposed on FIG. 9B;

FIG. 11A is a plan view of an upper gate pattern according to one or more embodiments;

FIG. 11B is an exemplary illustration in which the shape shown in FIG. 11A is superimposed on FIG. 10B;

FIG. 12A is a plan view of a lower conductive pattern according to one or more embodiments;

FIG. 12B is an exemplary illustration in which the shape shown in FIG. 11A is superimposed on FIG. 10B;

FIG. 13A is a plan view of an upper conductive pattern according to one or more embodiments; and

FIG. 13B is an exemplary illustration in which the shape shown in FIG. 13A is superimposed on FIG. 12B.

### DETAILED DESCRIPTION

References will now be made in detail to certain embodiments, of which examples are illustrated in the accompanying drawings, where like reference numerals refer to like elements throughout. Embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, embodiments are merely described below, by referring to the figures, to explain features of the present disclosure.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not be restricted to the thicknesses, ratios, dimensions, etc. illustrated in the drawings. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. The term “and/or” shall include the combination of a plurality of listed items or any of the plurality of listed items that can be defined by relevant elements. Expressions such as “at least one of” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

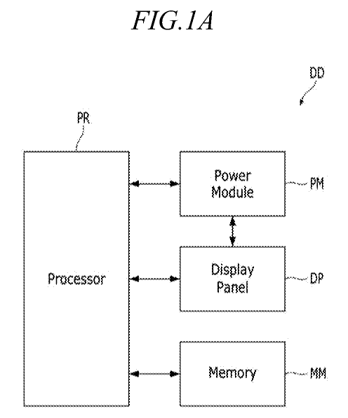

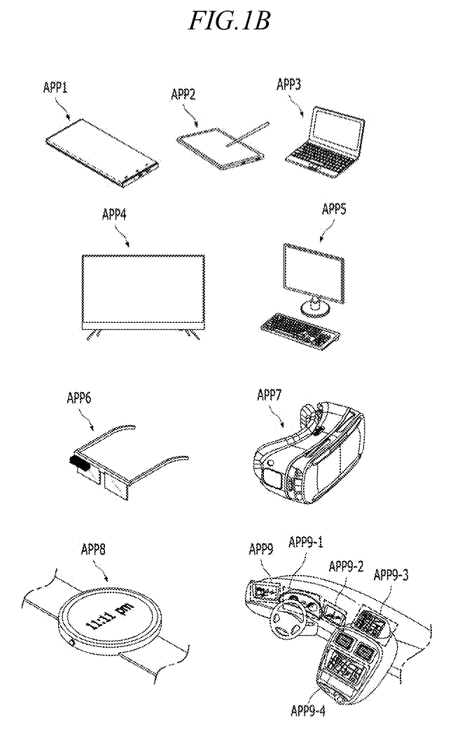

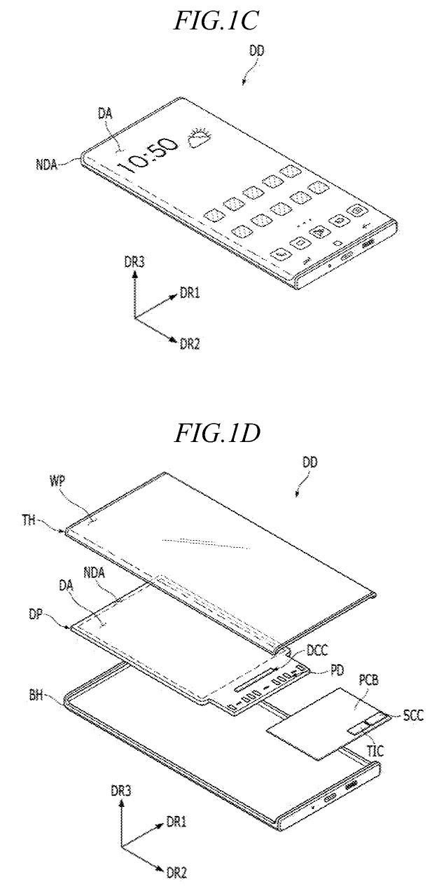

FIG. 1A illustrates an exemplary block diagram of an electronic device DD according to one or more embodiments.

A display panel DP according to one or more embodiments may be applied to various electronic devices DD. An electronic device DD according to one or more embodiments may include the above-described display panel DP and may further include modules or devices with supplementary functions in addition to the display panel DP.

Referring to FIG. 1A, an electronic device DD according to one or more embodiments may include a display panel DP, a processor PR, a memory MM, and a power module PM.

The processor PR may include at least one of a central processing unit (CPU), an application processor (AP), a graphics processing unit (GPU), a communication processor (CP), an image signal processor (ISP), and a controller.

The memory MM may have data and information stored therein for the operation of the processor PR or the display panel DP. When the processor PR executes an application stored in the memory MM, at least one of an image data signal and an input control signal may be transferred to the display panel DP, which may then process the received signals and output image information.

The power module PM may include a power supply module (i.e., a power supply circuit), such as a power adapter or a battery device, and a power conversion module (i.e., a power conversion circuit) configured to convert the power supplied by the power supply module into power required for the operation of the electronic device DD.

At least one of the above-described components of the electronic device DD may be included within the display panel DP according to embodiments. Additionally, certain individual modules included functionally within a single module may be provided within the display panel DP while other individual modules may be provided outside the display panel DP. For instance, the electronic device DD may include the display panel DP, and the processor PR, memory MM, and power module PM may be provided as other devices within the electronic device DD but not within the display panel DP.

FIG. 1B is an exemplary illustration of an electronic device DD according to one or more embodiments.

Referring to FIG. 1B, the display panel DP according to an embodiment may be applied to various electronic devices DD such as image-display electronic devices, including smartphones APP1, tablet PCs APP2, laptops APP3, TVs APP4, and desktop monitors APP5, wearable electronic devices, including smart glasses APP6, head-mounted displays APP7, and smartwatches APP8, and vehicle electronic devices APP9 - APP9-4, including instrument panels, center fascias, dashboards equipped with center information displays CID, or room mirror displays.

Hereinafter, the electronic device DD according to one or more embodiments is described based on a case that the electronic device DD is the smartphone APP1 shown in FIG. 1B.

FIG. 1C and FIG. 1D exemplarily illustrate an assembled perspective view and an exploded perspective view, respectively, of an electronic device DD according to one or more embodiments.

Referring to FIG. 1C and 1D, a display region DA and a non-display region NDA may be defined in the electronic device DD.

The display region DA may be a region where an image is displayed. The display region DA may be parallel to a plane defined by a first direction DR1 and a second direction DR2. A normal direction of the display region DA may be a third direction DR3. The non-display region NDA may be a region where an image is not displayed. The non-display region NDA may be a region surrounding the display region DA. However, the respective shapes of the display region DA and non-display region NDA shown in FIG. 1C and FIG. 1D are merely exemplarily illustrated, and therefore, the respective shapes of the display region DA and non-display region DNA may be modified as necessary.

Referring to FIG. 1C and FIG. 1D, the electronic device DD may include an upper housing TH, a lower housing BH, and a display panel DP.

The upper housing TH may include a window member WP and be disposed above the display panel.

The window member WP may be configured to allow penetration of incident light. Particularly, an image displayed in the display panel DP may penetrate through the window member WP to be viewed by a user. The window member WP may overlap with the display region DA. The window member WP may include a transparent material and allow penetration of light. The window member WP may include an insulating material. For example, the window member WP may include at least one of glass and plastic.

The lower housing BH may be disposed below the display panel DP. The lower housing BH may be configured to protect the display panel DP from an external impact. The lower housing BH may be configured to protect the display panel DP from an external impact. The lower housing BH may receive the display panel DP.

The display panel DP may be mounted in the electronic device DD shown in FIG. 1C and FIG. 1D. The display panel DP may have a display region DA and a non-display region NDA defined therein and overlapping with the display region DA and the non-display region NDA of the electronic device DD, respectively.

In one or more embodiments, the display panel DP may be a light-emitting display panel. For example, the display panel DP may be any one of an organic light-emitting display panel, a quantum dot light-emitting display panel, a micro light-emitting diode (LED) display panel, a liquid crystal display panel, an electrophoretic display panel, and an electrowetting display panel. A light-emission layer of an organic light-emitting display panel may include an organic light-emitting material. An inorganic light-emitting display panel may be based on an inorganic material and include a quantum dot light-emitting display panel and a micro light-emitting display panel. Hereinafter, a display panel DP is described based on an organic light-emitting display panel.

Although the electronic devices DD shown in FIG. 1C and FIG. 1D are illustrated as a smartphone, an electronic device DD is not limited thereto. In other embodiments, an electronic device DD may include a large-size display device and a small or medium-size display device. For instance, a large-size display device may include a television, a monitor, and a signboard. A small or medium-size display device may include a tablet, a built-in display of home appliances, a smartwatch, and a smartphone.

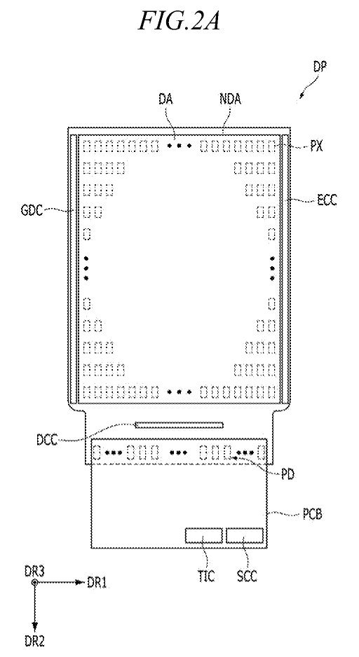

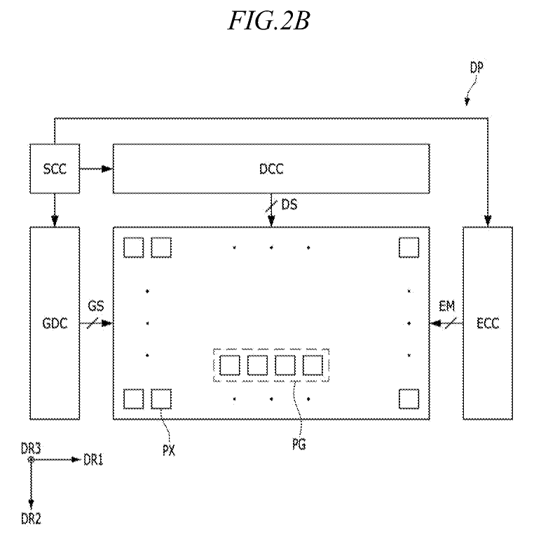

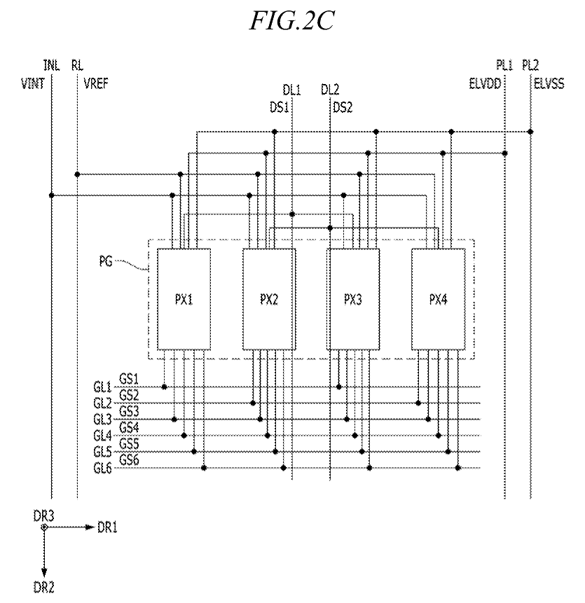

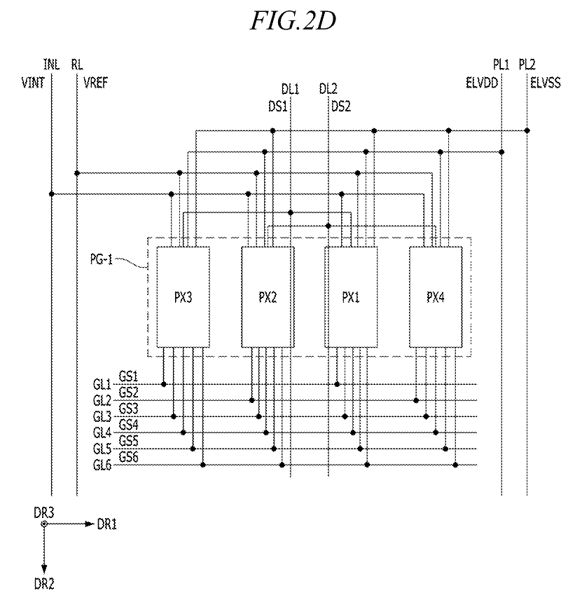

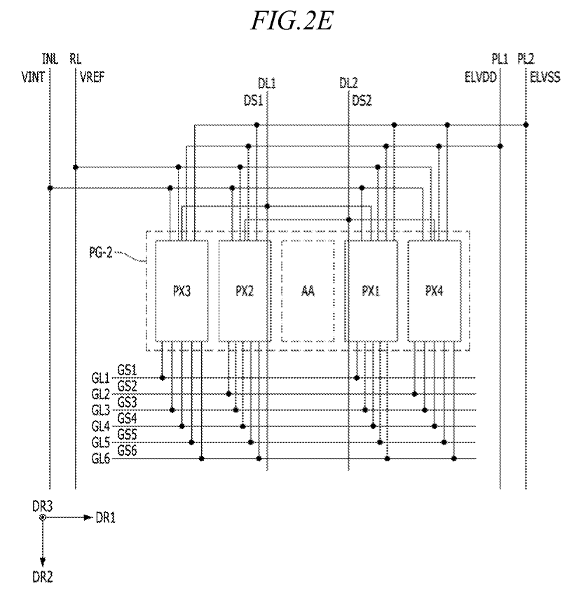

FIG. 2A is an exemplary plan view of a display panel DP according to one or more embodiments. FIG. 2B is an exemplary block diagram of a display panel DP according to one or more embodiments. FIGS. 2C through 2E are exemplary block diagrams of a pixel group PG, PG-1, and PG-2 among the plurality of pixels shown in FIG. 2B.

Referring to FIGS. 2A through 2E, the display panel may include gate driving circuit GDC, a light-emission control circuit ECC, a data driving circuit DCC, a printed circuit board PCB, an input sensor driving circuit TIC, a signal control circuit SCC, a plurality of pads PD, a first gate line GL1, a second gate line GL2, a first data line DL1, a second data line DL2, a first power line PL1, a second power line PL2, a third gate line GL3, a fourth gate line GL4, a fifth gate line GL5, a sixth gate line GL6, an initialization line INL, a first power line PL1, a second power line PL2, a standard power line RL, and a pixel PX.

The gate driving circuit GDC may be configured to receive a control signal from the signal control circuit SCC and provide a first gate signal GS1 and a second gate signal GS2 to the pixel PX through the third gate lines GL3 and the fourth gate lines GL4.

In one or more embodiments, the gate driving circuit GDC may be formed simultaneously with the pixels PX through a thin film process. For example, the gate driving circuit GDC may be mounted in a form of an oxide semiconductor thin film transistor (TFT) gate driver circuit (OSG) or an Amorphous Silicon TFT Gate driver circuit (ASG).

The light-emission control circuit ECC may be configured to receive a control signal from the signal control circuit SCC and provide a light-emission control signal EM to the pixel PX through the fifth gate line GL5 and the sixth gate line GL6. The light-emission control signal EM may be an electrical to control light-emission and include a third gate signal GS3 and a fourth gate signal GS4.

The data driving circuit DDC may be configured to receive a control signal from the signal control circuit SCC and provide a first data signal DS1 and a second data signal DS2 to the pixel PX through the first data lines DL1 and the second data lines DL2.

The input sensor driving circuit TIC and the signal control circuit SCC may be mounted on the printed circuit board PCB and configured to receive an electrical signal from the plurality of pads PD. The input sensor driving circuit TIC may be configured to process a signal corresponding to a user’s touch and a signal corresponding to a pressure applied from outside.

The signal control circuit SCC (e.g., a timing controller) may be configured to control at least any one of the input sensor driving circuit TIC, the gate driving circuit GDC, the data driving circuit DCC, and the light-emission control circuit ECC. The signal control circuit SCC may be configured to receive an image data and a control signal from an external graphic control unit. The control signal may include a vertical synchronization signal, a horizontal synchronization signal, a data enable signal, and a clock signal. The vertical synchronization signal may be a signal for distinguishing frame intervals. The horizontal synchronization signal may be a signal for distinguishing horizontal intervals (i.e., a row- distinguishing signal).

Although FIG. 2A illustrates that the gate driving circuit GDC and the light-emission control circuit ECC are separate components and spaced apart from each other, the gate driving circuit GDC and the light-emission control circuit ECC according to the present disclosure are not limited thereto. In other embodiments, the gate driving circuit GDC and the light-emission control circuit ECC may be provided as one component.

The first data line DL1 may be configured to provide a first data signal DS1. In one or more embodiments, the first data line DL1 may be configured to provide a first data signal DS1 to a first pixel PX1 and a third pixel PX3.

The second data line DL2 may be configured to provide a second data signal DS2. In one or more embodiments, the second data line DL2 may be configured to provide a second data signal DS2 to a second pixel PX2 and a fourth pixel PX4.

That is, the first pixel PX1 and the third pixel PX3 may share the first data signal DS1, and the second pixel PX2 and the fourth pixel PX4 may share the second data signal DS2. Accordingly, power consumption may be reduced when each of the first data signal DS1 and the second data signal DS2 is shared compared to when each of the first data signal DS1 and the second data signal DS2 is not shared.

The first gate line GL1 may be configured to provide a first gate signal GS1. In one or more embodiments, the first gate line GL1 may be configured to provide a first gate signal GS1 to the first pixel PX1 and the third pixel PX3.

The second gate line GL2 may be configured to provide a second gate signal GS2. In one or more embodiments, the second gate line GL2 may be configured to provide a second gate signal GS2 to the second pixel PX2 and the fourth pixel PX4.

The third gate line GL3 may be configured to provide a third gate signal GS3. In one or more embodiments, the third gate line GL3 may be configured to provide a third gate signal GS3 to the first pixel through the fourth pixel PX1~PX4.

The fourth gate line GL4 may be configured to provide a fourth gate signal GS4. In one or more embodiments, the fourth gate line GL4 may be configured to provide a fourth gate signal GS4 to the first pixel through the fourth pixel PX1~PX4.

The fifth gate line GL5 may be configured to provide a fifth gate signal GS5. In one or more embodiments, the fifth gate line GL5 may be configured to provide a fifth gate signal GS5 to the first pixel through the fourth pixel PX1~PX4.

The sixth gate line GL6 may be configured to provide a sixth gate signal GS6. In one or more embodiments, the sixth gate line GL6 may be configured to provide a sixth gate signal GS6 to the first pixel through the fourth pixel PX1~PX4.

In one or more embodiments, the first gate line GL1 and the second gate line GL2 may be spaced apart from the first pixel through the fourth pixel PX1~PX4 in the second direction DR2. In one or more embodiments, the first gate line GL1 may be disposed closest to the second gate line GL2 among the second gate line through the sixth gate line GL2 through GL6. In one or more embodiments, the first gate line GL1 and the second gate line GL2 may be interposed between the first pixel through the fourth pixel PX1 through PX4 and the third gate line through the sixth gate line GL3 through GL6.

The initialization line INL may be configured to provide an initialization signal VINT. In one or more embodiments, the initialization line INL may be configured to provide an initialization signal VINT to the first pixel through the fourth pixel PX1~PX4. However, FIGS. 2C through 2E are merely provided as examples, and a connection relationship between the initialization line INL and the plurality of pixels PX may be modified as necessary.

The first power line PL1 may be configured to provide a first power signal ELVDD. In one or more embodiments, the first power line PL1 may be configured to provide a first power signal ELVDD to the first pixel through the fourth pixel PX1~PX4. However, FIGS. 2C through 2E are merely provided as examples, and a connection relationship between the first power line PL1 and the plurality of pixels PX may be modified as necessary.

The second power line PL2 may be configured to provide a second power signal ELVSS. In one or more embodiments, the second power line PL2 may be configured to provide a second power signal ELVSS to the first pixel through the fourth pixel PX1~PX4. However, FIGS. 2C through 2E are merely provided as examples, and a connection relationship between the second power line PL2 and the plurality of pixels PX may be modified as necessary.

The reference voltage line RL may be configured to provide a reference voltage signal VREF. The reference voltage line RL may be configured to provide a reference voltage signal VREF to the first pixel through the fourth pixel PX1~PX4. However, FIGS. 2C through 2E are merely provided as examples, and a connection relationship between the reference voltage line RL and the plurality of pixels PX may be modified as necessary.

In one or more embodiments, at least any one of the first data line DL1, the second data line DL2, the first gate line GL1, the second gate line GL2, the third gate line GL3, the fourth gate line GL4, the fifth gate line GL5, the sixth gate line GL6, the initialization line INL, the first power line PL1, the second power line PL2, and the reference voltage line RL may be omitted.

In one or more embodiments, the first gate line GL1, the second gate line GL2, the first data line DL1, the second data line DL2, the first power line PL1, the second power line PL2, the third gate line GL3, the fourth gate line GL4, the fifth gate line GL5, the sixth gate line GL6, the initialization line INL, the first power line PL1, the second power line PL2, the reference voltage line RL, and the pixel PX may each be provided in a plurality.

A pixel group PG may be a portion of the plurality of pixels. The pixel group PG may include a first pixel PX1, a second pixel PX2, a third pixel PX3, and a fourth pixel PX4. The first pixel PX1 may be configured to emit first light, the second pixel PX2 may be configured to emit second light, the third pixel PX3 may be configured to emit third light, and the fourth pixel PX4 may be configured to emit fourth light. In one or more embodiments, the pixel group PG may be provided in a plurality.

Referring to FIG. 2C, the pixel group PG according to one or more embodiments may have a first pixel PX1, a second pixel PX2, a third pixel PX3, and a fourth pixel PX4 sequentially disposed along the first direction DR1. That is, the second pixel PX2 may be disposed between the first pixel PX1 and the third pixel PX3, and the third pixel PX3 may be disposed between the second pixel PX2 and the fourth pixel PX4.

Referring to FIG. 2D, the pixel group PG-1 according to one or more embodiments may have a third pixel PX3, a second pixel PX2, a first pixel PX1, and a fourth pixel PX4 sequentially disposed along the first direction DR1. That is, the second pixel PX2 may be disposed between the third pixel PX3 and the first pixel PX1, and the first pixel PX1 may be disposed between the second pixel PX2 and the fourth pixel PX4.

Referring to FIG. 2E, the pixel group PG-2 according to one or more embodiments may have a pre-determined area AA defined between a second pixel PX2 and a third pixel PX3, or between a second pixel PX2 and a first pixel PX1. In one or more embodiments, any one of a transparent, pre-determined material and optical sensor may be disposed on the pre-determined region AA. In other embodiments, a fifth pixel configured to emit fifth light different from the first light through the fourth light may be disposed on the pre-determined region AA. For example, the fifth light may be white light.

In one or more embodiments, a respective wavelength of the second light and the fourth light may be greater than a wavelength of the third light and smaller than a wavelength of the first light. For example, the first light may be red light, the third light may be blue light, and the second light and the fourth light may each be green light.

In other embodiments, the first light may have a color of a wavelength in a first range, the second light may have a color of a wavelength in a second range, the third light may have a color of a wavelength in a third range, and the fourth light may have a color of a wavelength in a fourth range. The first range may be greater than or equal to 625 nm and smaller than or equal to 750 nm, and the third range may be greater than or equal to 450 nm and smaller than or equal to 500 nm. The second range and the fourth range may each be greater than or equal to 520 nm and smaller than or equal to 570 nm.

In other embodiments, the second light and the fourth light may have a same wavelength different from a wavelength of the first light and the third light. For example, the second light and the fourth light may each be green light, and the first light and the third light may each be any one of red light, blue light and green light. However, the first light and the third light are not limited thereto, and it is sufficient as long as each of the first light and the third light is not green light.

In one or more embodiments, at least a portion of the first data line DL1 may overlap with a second pixel circuit PC2, and at least a portion of the second data line DL2 may overlap with the third pixel circuit PC3. That is, the first data line DL1 overlapping with the second pixel PX2 may be configured to provide a first data signal DS1 to the first pixel PX1 and the third pixel PX3, and the second data line DL2 overlapping with the third pixel PX3 may be configured to provide a second data signal DS2 to the second pixel PX2 and the fourth pixel PX4.

A shape of the first pixel circuit PC1 may be designed to be similar to a shape of the third pixel circuit PC3, and a shape of the second pixel circuit PC2 may be designed to be similar to a shape of the fourth pixel circuit PC4. Accordingly, as a deviation of a distance between the data lines DL1 and DL2 and the pixel circuits PC1, PC2, PC3, and PC4 is reduced, a luminance deviation between the pixels PX1, PX2, PX3, and PX4 may be reduced.

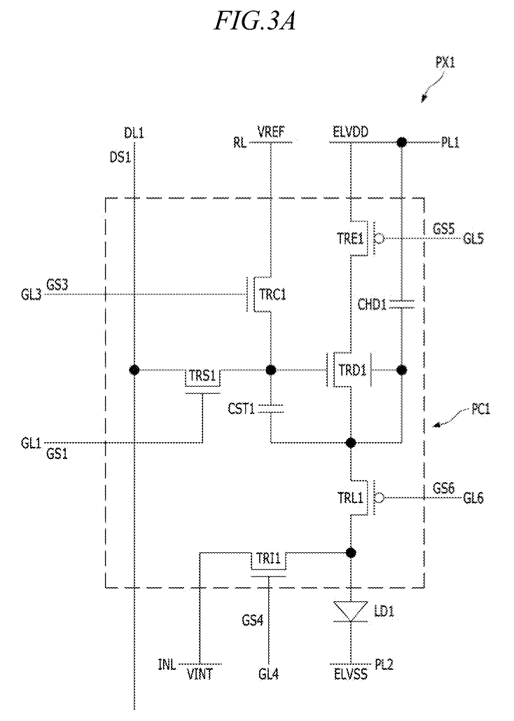

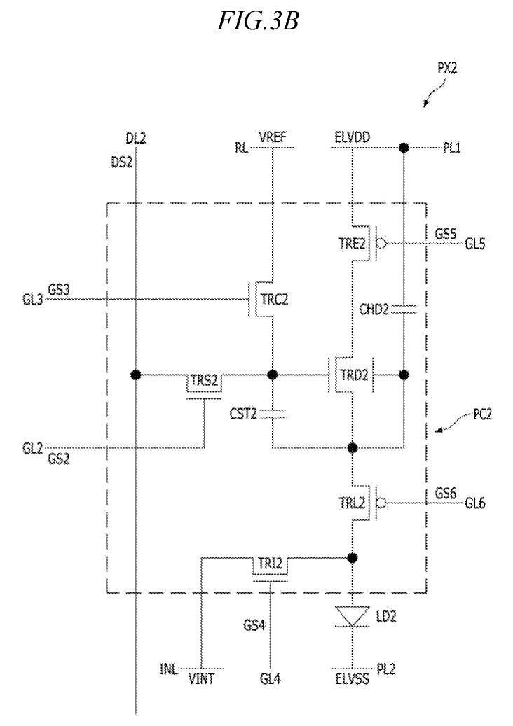

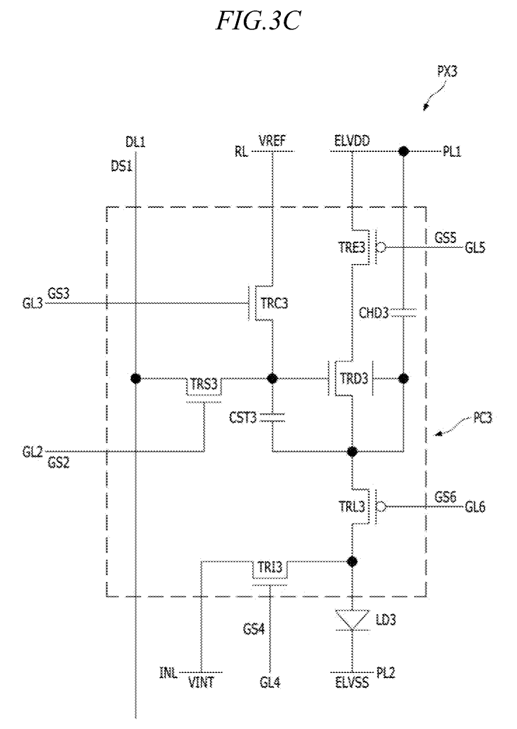

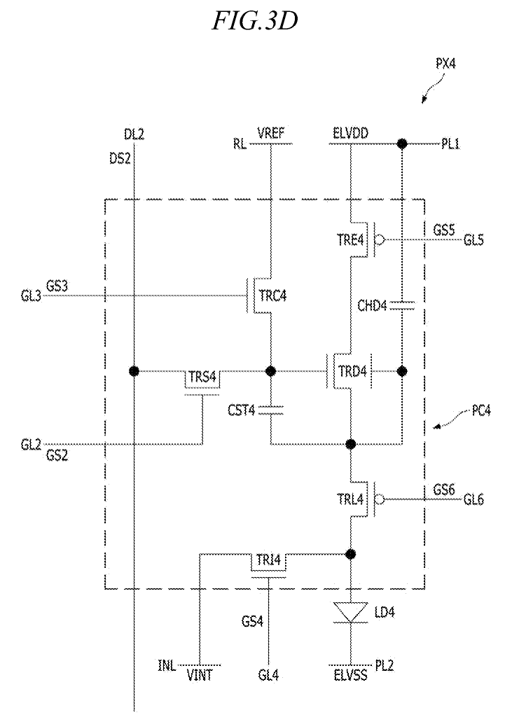

FIGS. 3A through 3D are exemplary equivalent circuit diagrams of a first pixel PX1 through a fourth pixel PX4 according to one or more embodiments.

Referring to FIG. 3A, the first pixel PX1 may include a first pixel circuit PC1 and a first light-emitting diode LD1.

The first pixel circuit PC1 may be configured to control a current value flowing through the first light-emitting diode LD1 in response to the first data signal DS1. The first pixel circuit PC1 may include a first driving transistor TRD1, a first switching transistor TRS1, a first compensation transistor TRC1, a first initialization transistor TRI1, a first main light-emission control transistor TRE1, a first sub light-emission control transistor TRL1, a first compensation capacitor CST1, and a first stabilization capacitor CHD1.

In one or more embodiments, at least one of the first driving transistor TRD1, the first switching transistor TRS1, the first compensation transistor TRC1, the first initialization transistor TRI1, the first main light-emission control transistor TRE1, the first sub light-emission control transistor TRL1, the first compensation capacitor CST1, and the first stabilization capacitor CHD1 may be omitted.

An input electrode may refer to any one of a source electrode and a drain electrode, an output electrode may refer to the other of the source electrode and the drain electrode, a control electrode may refer to a gate electrode, and a sub control electrode may refer to a back-gate electrode.

The first driving transistor TRD1 may be electrically connected to the first light-emitting diode LD1. The first driving transistor TRD1 may include an input electrode, an output electrode, a control electrode, and a sub control electrode. A current flowing through the first light-emitting diode LD1 may be controlled based on a voltage of the control electrode of the first driving transistor TRD1.

The first switching transistor TRS1 may be controlled by a first gate signal GS1. The first switching transistor TRS1 may be disposed between the first data line DL1 and the control electrode of the first driving transistor TRD1. The first switching transistor TRS1 may be turned on by the first gate signal GS1 to transfer at least a portion of the first data signal DS1 to the control electrode of the first driving transistor TRD1.

The first compensation transistor TRC1 may be disposed between the reference voltage line RL and the control electrode of the first driving transistor TRD1. The first compensation transistor TRC1 may be controlled by a third gate signal GS3. The first compensation transistor TRC1 may be turned on by the third gate signal GS3 to transfer at least a portion of the reference voltage signal VREF to the control electrode of the first driving transistor TRD1.

The first initialization transistor TRI1 may be disposed between the initialization line INL and the first light-emitting diode LD1. The first initialization transistor TRI1 may be controlled by a fourth gate signal GS4. The first initialization transistor TRI1 may be turned on by the fourth gate signal GS4 to transfer at least a portion of the initialization signal VINT to an anode electrode of the first light-emitting diode LD1.

The first main light-emission control transistor TRE1 may be disposed between the first driving transistor TRD1 and the first power line PL1. The first main light-emission control transistor TRE1 may include an input electrode, a control electrode, and an output electrode. The first main light-emission control transistor TRE1 may be turned on by the fifth gate signal GS5 to transfer at least a portion of the first power signal ELVDD to the input electrode of the first driving transistor TRD1.

The first sub light-emission control transistor TRL1 may be disposed between the first driving transistor TRD1 and the first light-emitting diode LD1. The first sub light-emission control transistor TRL1 may include an input electrode, a control electrode, and an output electrode. The first sub light-emission control transistor TRL1 may be turned on by the sixth gate signal GS6 to electrically connect the output electrode of the first driving transistor TRD1 and the first light-emitting diode LD1.

The first stabilization capacitor CH1 may be disposed among the output electrode of the first driving transistor TRD1, the sub control electrode of the first driving transistor TRD1, and the first power line PL1. The first stabilization capacitor CHD1 may be configured to store an amount of charge corresponding to a potential difference between any one of the output electrode of the first driving transistor TRD1 and the sub control electrode of the first driving transistor TRD1, and the first power line PL1.

The first light-emitting diode LD1 may be configured to emit light of a pre-determined luminance in response to a current provided from the first pixel circuit PC1. For the above, a voltage of the first power signal ELVDD may be set to be greater than a voltage of the second power signal ELVSS. An anode electrode of the first light-emitting diode LD1 may be electrically connected to the output electrode of the first sub light-emission control transistor TRL1. A second power signal ELVSS may be provided to the first light-emitting diode LD1. In one or more embodiments, the first light-emitting diode LD1 may be an organic light-emitting diode (OLED). However, the first light-emitting diode LD1 is not limited thereto, and it is sufficient as long as the first light-emitting diode LD1 emits light in response to an applied current.

In one or more embodiments, the first driving transistor TRD1, the first switching transistor TRS1, the first compensation transistor TRC1, the first initialization transistor TRI1, the first main light-emission control transistor TRE1, and the first sub light-emission control transistor TRL1 may each be an oxide thin film transistor. In other embodiments, the first driving transistor TRD1, the first switching transistor TRS1, the first compensation transistor TRC1, the first initialization transistor TRI1, the first main light-emission control transistor TRE1, and the first sub light-emission control transistor TRL1 may each be a LTPS (Low-Temperature Polycrystalline Silicon) thin film transistor. However, the present disclosure is not limited thereto, and a first pixel PX1 may be formed of various combinations of at least one of an oxide thin film transistor and Low-Temperature Polycrystalline Silicon (LTPS) thin film transistor.

In one or more embodiments, the first driving transistor TRD1, the first switching transistor TRS1, the first compensation transistor TRC1, the first initialization transistor TRI1, the first main light-emission control transistor TRE1, and the first sub light-emission control transistor TRL1 may each be an n-type metal-oxide-semiconductor field-effect transistor (NMOSFET). In other embodiments, the first driving transistor TRD1, the first switching transistor TRS1, the first compensation transistor TRC1, the first initialization transistor TRI1, the first main light-emission control transistor TRE1, and the first sub light-emission control transistor TRL1 may each be a p-type metal-oxide-semiconductor field-effect transistor (PMOSFET). However, a first pixel PX1 is not limited thereto, and the first pixel PX1 may be formed of various combinations of at least one of NMOSFET and PMOSFET.

Referring to FIG. 3B, the second pixel circuit PC2 may be configured to control current flowing through the second light-emitting diode LD2 in response to the second data signal DS2. The second pixel circuit PC2 may include a second driving transistor TRD2, a second switching transistor TRS2, a second compensation transistor TRC2, a second initialization transistor TRI2, a second main light-emission control transistor TRE2, a second sub light-emission control transistor TRL2, a second compensation capacitor CST2, and a second stabilization capacitor CHD2.

In one or more embodiments, at least one of the second driving transistor TRD2, the second switching transistor TRS2, the second compensation transistor TRC2, the second initialization transistor TRI2, the second main light-emission control transistor TRE2, the second sub light-emission control transistor TRL2, the second compensation capacitor CST2, and the second stabilization capacitor CHD2 may be omitted.

Descriptions about other elements of the second pixel PX2 other than the above are substantially the same as the descriptions in FIG. 3A, and thus will be omitted.

Referring to FIG. 3C, the third pixel PX3 may include a third pixel circuit PC3 and a third light-emitting diode LD3.

The third pixel circuit PC3 may be configured to control current flowing through the third light-emitting diode LD3 in response to a third signal DS3. The third pixel circuit PC3 may include a third driving transistor TRD3, a third switching transistor TRS3, a third compensation transistor TRC3, a third initialization transistor TRI3, a third main light-emission control transistor TRE3, a third sub light-emission control transistor TRL3, a third compensation capacitor CST3, and a third stabilization capacitor CHD3.

In one or more embodiments, at least any one of the third driving transistor TRD3, the third switching transistor TRS3, the third compensation transistor TRC3, the third initialization transistor TRI3, the third main light-emission control transistor TRE3, the third sub light-emission control transistor TRL3, the third compensation capacitor CST3, and the third stabilization capacitor CHD3 may be omitted.

Descriptions about other elements of the third pixel PX3 other than the above are substantially the same as the descriptions in FIG. 3A, and thus will be omitted.

Referring to FIG. 3D, the fourth pixel PX4 may include a fourth pixel circuit PC4 and a fourth light-emitting diode LD4.

The fourth pixel circuit PC4 may be configured to control current flowing through the fourth light-emitting diode LD4 in response to a fourth data signal DS4. The fourth pixel circuit PC4 may include a fourth driving transistor TRD4, a fourth switching transistor TRS4, a fourth compensation transistor TRC4, a fourth initialization transistor TRI4, a fourth main light-emission control transistor TRE4, a fourth sub light-emission control transistor TRL4, a fourth compensation capacitor CST4, and a fourth stabilization capacitor CHD4.

In one or more embodiments, at least one of the fourth driving transistor TRD4, the fourth switching transistor TRS4, the fourth compensation transistor TRC4, the fourth initialization transistor TRI4, the fourth main light-emission control transistor TRE4, the fourth sub light-emission control transistor TRL4, the fourth compensation capacitor CST4, and the fourth stabilization capacitor CHD4 may be omitted.

Descriptions about other elements of the fourth pixel PX4 other than the above are substantially the same as the descriptions in FIG. 3A, and thus will be omitted.

In one or more embodiments, the first switching transistor TRS1 and the third switching transistor TRS3 may be controlled by the first gate signal GS1, and the second switching transistor TRS2 and the fourth switching transistor TRS4 may be controlled by the second gate signal GS2.

In one or more embodiments, the first compensation transistor through the fourth compensation transistor TRC1~TRC4 may each be controlled by the third gate signal GS3.

In one or more embodiments, the first initialization transistor through the fourth initialization transistor TRI1~TRI4 may each be controlled by the fourth gate signal GS4.

In one or more embodiments, the first main light-emission control transistor through the fourth main light-emission control transistor TRE1~TRE4 may each be controlled by the fifth gate signal GS5.

In one or more embodiments, the first sub light-emission control transistor through the fourth sub light-emission control transistor TRL1~TRL4 may each be controlled by the sixth gate signal GS6.

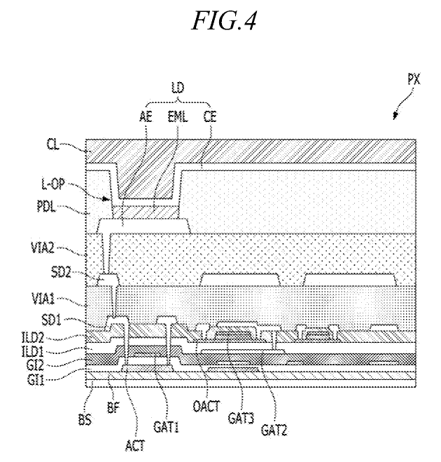

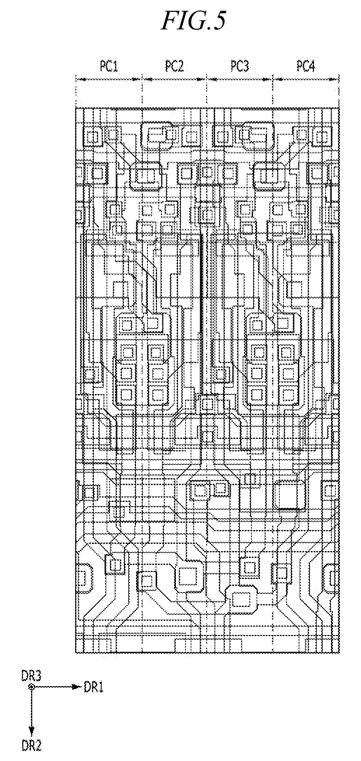

FIG. 4 illustrates a portion of an exemplary cross-sectional view of a display panel DP according to one or more embodiments.

Referring to FIG. 4, the display panel DP according to one or more embodiments may include a base substrate BS, a buffer layer BF, a semiconductor pattern ACT, OACT, a gate insulating layer GI1, GI2, a gate pattern GAT1, GAT2, GAT3, an interlayer insulating layer ILD1, ILD2, a conductive pattern SD1, SD2, a via layer VIA1, VIA2, a pixel defining film PDL, and an encapsulation layer CL.

The semiconductor pattern ACT, OACT may include at least any one of a lower semiconductor pattern ACT and an upper semiconductor pattern OACT. The lower semiconductor pattern ACT and the upper semiconductor pattern OACT may be disposed on different layers from each other.

The gate insulating layer GI1, GI2 may include a first gate insulating layer GI1 and a second gate insulating layer GI2.

The gate pattern GAT1, GAT2, GAT3 may include at least one of a sub gate pattern GAT1, a lower gate pattern GAT2, and an upper gate pattern GAT3. The sub gate pattern GAT1, the lower gate pattern GAT2, and the upper gate pattern GAT3 may be disposed on different layers from one another.

The interlayer insulating layer ILD1, ILD2 may include a first interlayer insulating layer ILD1 and a second interlayer insulating layer ILD2.

The conductive pattern SD1, SD2 may include at least one of a lower conductive pattern SD1 and an upper conductive pattern SD2.

The via layer VIA1, VIA2 may include a first via layer VIA1 and a second via layer VIA2.

The buffer layer BF may be disposed between the base substrate BS and the lower semiconductor pattern ACT. The buffer layer BF may include at least any one of an inorganic material and an organic material. For example, the buffer layer BF may include at least any one of silicon nitride, silicon oxynitride, silicon oxide, titanium oxide, aluminum oxide and an acryl-based organic material.

The lower semiconductor pattern ACT may be disposed on the buffer layer BF. The lower semiconductor pattern ACT may include a semiconductor material. In one or more embodiments, the semiconductor material may include at least any one of an amorphous silicon semiconductor, a polycrystalline silicon semiconductor, a metal oxide semiconductor, a crystalline oxide semiconductor, an amorphous oxide semiconductor. For example, the oxide semiconductor may include at least any one of indium-tin oxide (ITO), indium-gallium-zinc oxide (IGZO), zinc oxide (ZnO), indium-zinc oxide (IZnO), zinc-indium oxide (ZIO), indium oxide (InO), titanium oxide (TiO), indium-zinc-tin oxide (IZTO), and zinc-tin oxide (ZTO).

The first gate insulating layer GI1 may be disposed on the buffer layer BF. The first gate insulating layer GI1 may be on the lower semiconductor pattern ACT. For example, the first gate insulating layer GI1 may cover the lower semiconductor pattern ACT. The first gate insulating layer GI1 may include at least any one of an organic insulating material and an inorganic insulating material. For example, the first gate insulating layer GI1 may include at least any one of polysiloxane, silicon nitride, silicon oxide, silicon oxynitride, polyacrylic compound, polyimide-based compound, fluorine-based carbon compound, and benzocyclobutene compound. The first gate insulating layer GI1 may further include at least one individual layer that includes an insulating material.

The sub gate pattern GAT1 may be disposed on the first gate insulating layer GI1. At least a portion of the sub gate pattern GAT1 may overlap with the lower semiconductor pattern ACT. The sub gate pattern GAT1 may include metal. For example, the sub gate pattern GAT1 may include at least any one of gold (Au), silver (Ag), aluminum (Al), molybdenum (Mo), chromium (Cr), titanium (Ti), nickel (Ni), neodymium (Nd), and copper (Cu).

The second gate insulating layer GI2 may be disposed on the first gate insulating layer GI1. The second gate insulating layer GI2 may be one least any one of the sub gate pattern GAT1 and the upper semiconductor pattern OACT. For example, the second gate insulating layer GI2 may cover at least any one of the sub gate pattern GAT1 and the upper semiconductor pattern OACT. The second gate insulating layer GI2 may include at least any one of an organic insulating material and an inorganic insulating material. For example, the second gate insulating layer GI2 may include at least any one of polysiloxane, silicon nitride, silicon oxide, silicon oxynitride, polyacrylic compound, polyimide-based compound, fluorine-based carbon compound, and benzocyclobutene compound. The second gate insulating layer GI2 may further include at least one individual layer that includes an insulating material.

The lower gate pattern GAT2 may be disposed on the second gate insulating layer GI2. The lower gate pattern GAT2 may include metal. For example, the lower gate pattern GAT2 may include at least any one of gold (Au), silver (Ag), aluminum (Al), molybdenum (Mo), chromium (Cr), titanium (Ti), nickel (Ni), neodymium (Nd), and copper (Cu).

The first interlayer insulating layer ILD1 may be disposed on the second gate insulating layer GI2. The first interlayer insulating layer ILD1 may be on the lower gate pattern GAT2. For example, the first interlayer insulating layer ILD1 may cover the lower gate pattern GAT2. The first interlayer insulating layer ILD1 may include an insulating material. For example, the first interlayer insulating layer ILD1 may include at least any one of polysiloxane, silicon nitride, silicon oxide, and silicon oxynitride.

The upper gate pattern GAT3 may be disposed on the second gate insulating layer GI2. The upper gate pattern GAT3 may include metal. For example, the upper gate pattern GAT3 may include at least any one of gold (Au), silver (Ag), aluminum (Al), molybdenum (Mo), chromium (Cr), titanium (Ti), nickel (Ni), neodymium (Nd), and copper (Cu).

The second interlayer insulating layer ILD2 may be disposed on the first interlayer insulating layer ILD1. The second interlayer insulating layer ILD2 may be on the upper gate pattern GAT3. For example, the second interlayer insulating layer ILD2 may cover the upper gate pattern GAT3. The second interlayer insulating layer ILD2 may include an insulating material. For example, the second interlayer insulating layer ILD2 may include at least any one of polysiloxane, silicon nitride, silicon oxide, and silicon oxynitride.

The lower conductive pattern SD1 may be disposed on the second interlayer insulating layer ILD2. The lower conductive pattern SD1 may be electrically connected to at least any one of the lower semiconductor pattern ACT, the lower gate pattern GAT2, and the upper semiconductor pattern OACT. The lower conductive pattern SD1 may include metal. For example, the lower conductive pattern SD1 may include at least any one of gold (Au), silver (Ag), aluminum (Al), molybdenum (Mo), chromium (Cr), titanium (Ti), nickel (Ni), neodymium (Nd), and copper (Cu).

The first via layer VIA1 may be disposed on the second interlayer insulating layer ILD2 and on the lower conductive pattern SD1. For example, the first via layer VIA1 may cover the lower conductive pattern SD1.

The upper conductive pattern SD2 may penetrate through the first via layer VIA1 to make contact with at least a portion of the lower conductive pattern SD1.

The second via layer VIA2 may be disposed on the first via layer VIA1 and the upper conductive pattern SD2. For example, the second via layer VIA2 may cover the upper conductive pattern SD2.

The pixel defining film PDL may be disposed on the second via layer VIA2. The pixel defining film PDL may have a light-emitting diode opening part L-OP defined therein, and the light-emitting diode LD may be disposed in the light-emitting diode opening part L-OP.

The light-emitting diode LD may be disposed on the first via layer VIA1 and the second via layer VIA2. The light-emitting diode LD may include an anode electrode AE, a light-emission layer EML, and a cathode electrode CE. The anode electrode AE may be electrically connected to at least any one of the lower semiconductor pattern ACT, the lower gate pattern GAT2, and the upper semiconductor pattern OACT through the lower conductive pattern SD1 and the upper conductive pattern SD2.

The encapsulation layer CL may be on (and for example may cover) the light-emitting diode LD to protect the light-emitting diode LD from oxygen or moisture. For example, the encapsulation layer CL may include at least any one of silicon oxide, silicon nitride, and silicon oxynitride. The encapsulation layer CL may include at least any one of an organic material and an inorganic material. In other embodiments, the encapsulation layer CL may further include at least one individual layer that includes at least any one of an organic material and an inorganic material.

FIG. 5 is an exemplary illustration of a shape in which a semiconductor pattern ACT, OACT, a gate pattern GAT1, GAT2, GAT3, and a conductive pattern SD1, SD2 overlap one another according to one or more embodiments.

Referring to FIG. 5, the first pixel circuit through the fourth pixel circuit PC1~PC4 shown in FIGS. 3A through 3D may be defined on the semiconductor pattern ACT, OACT, the gate pattern GAT1, GAT2, GAT3, and the conductive pattern SD1, SD2.

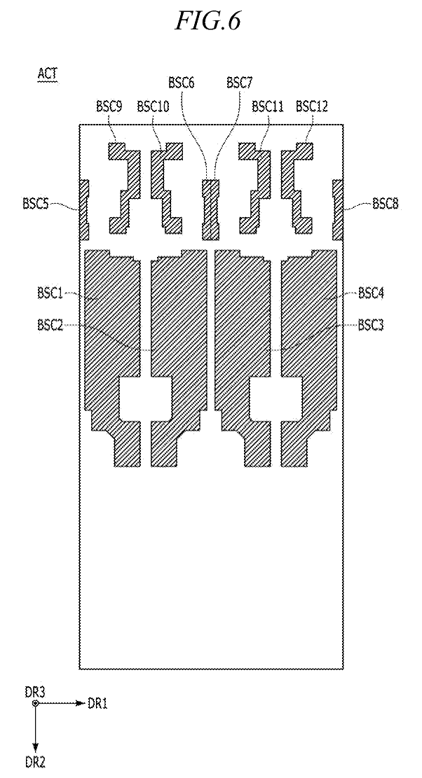

FIGS. 6 through 13B each illustrates at least any one of the semiconductor pattern ACT, OACT, the gate pattern GAT1, GAT2, GAT3, and the conductive pattern SD1, SD2 shown in FIG. 5.

Referring to FIGS. 6 through 13B, the lower semiconductor pattern ACT, the sub gate pattern GAT1, the lower gate pattern GAT2, the upper semiconductor pattern OACT, the upper gate pattern GAT3, the lower conductive pattern SD1, and the upper conductive pattern SD2 may be sequentially disposed along the third direction DR3. That is, the upper conductive pattern SD2 may be disposed uppermost, and the lower semiconductor pattern ACT may be disposed lowermost.

FIG. 6 is a plan view of a lower semiconductor pattern ACT according to one or more embodiments.

Referring to FIG. 6, the lower semiconductor pattern ACT may include at least any one of first lower semiconductor unit (i.e., portion) through twelfth lower semiconductor unit BSC1~BSC12.

The first lower semiconductor unit through the lower semiconductor unit BSC1~BSC4 may be spaced apart from one another and sequentially disposed along the first direction DR1. That is, the second lower semiconductor unit BSC2 may be disposed between the first lower semiconductor unit BSC1 and the third lower semiconductor unit BSC3, and the third lower semiconductor unit BSC3 may be disposed between the second lower semiconductor unit BSC2 and the fourth lower semiconductor unit BSC4. In one or more embodiments, a shape of the first lower semiconductor unit BSC1 may be same as a shape of the third lower semiconductor unit BSC3, and a shape of the second lower semiconductor unit BSC2 may be same as a shape of the fourth lower semiconductor unit BSC4.

The fifth lower semiconductor unit through the eighth lower semiconductor unit BSC5~BSC8 may be sequentially disposed along the first direction DR1. That is, the sixth lower semiconductor unit BSC6 may be disposed between the fifth lower semiconductor unit BSC5 and the seventh lower semiconductor unit BSC7, and the seventh lower semiconductor unit BSC7 may be disposed between the sixth lower semiconductor unit BSC6 and the eighth lower semiconductor unit BSC8. In one or more embodiments, a shape of the fifth lower semiconductor unit BSC5 may be same as a shape of the seventh lower semiconductor unit BSC7, and a shape of the sixth lower semiconductor unit BSC6 may be same as a shape of the eighth lower semiconductor unit BSC8.

The ninth lower semiconductor unit through the twelfth lower semiconductor unit BSC9~BSC12 may be spaced apart from one another and sequentially disposed along the first direction DR1. That is, the tenth lower semiconductor unit BSC10 may be disposed between the ninth lower semiconductor unit BSC9 and the eleventh lower semiconductor unit BSC11, and the eleventh lower semiconductor unit BSC11 may be disposed between the tenth lower semiconductor unit BSC10 and the twelfth lower semiconductor unit BSC12. In one or more embodiments, a shape of the ninth lower semiconductor unit BSC9 may be same as a shape of the eleventh lower semiconductor unit BSC11, and a shape of the tenth lower semiconductor unit BSC10 may be same as a shape of the twelfth lower semiconductor unit BSC12.

In one or more embodiments, the first lower semiconductor unit through the sixteenth lower semiconductor unit BSC1~BSC16 may each be an oxide semiconductor. The oxide semiconductor may be at least any one of a metal oxide semiconductor, a crystalline oxide semiconductor, and an amorphous oxide semiconductor. For example, the oxide semiconductor may include at least any one of indium-tin oxide (ITO), indium-gallium-zinc oxide (IGZO), zinc oxide (ZnO), indium-zinc oxide (IZnO), zinc-indium oxide (ZIO), indium oxide (InO), titanium oxide (TiO), indium-zinc-tin oxide (IZTO), and zinc-tin oxide (ZTO).

In other embodiments, the first lower semiconductor unit through the sixteenth lower semiconductor unit BSC1~BSC16 may each include a silicon semiconductor. The silicon semiconductor may include at least any one of amorphous silicon and polycrystalline silicon. For example, the first lower semiconductor unit through the sixteenth lower semiconductor unit BSC1~BSC16 may each include LTPS (Low-Temperature Polycrystalline Silicon). However, the first lower semiconductor unit through the sixteenth lower semiconductor unit BSC1~BSC16 is not limited thereto, and the first lower semiconductor unit through the sixteenth lower semiconductor unit BSC1~BSC16 may be formed of various combinations of an oxide semiconductor and a silicon semiconductor.

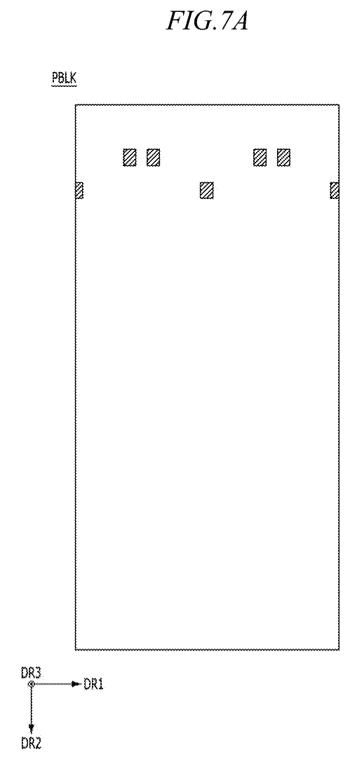

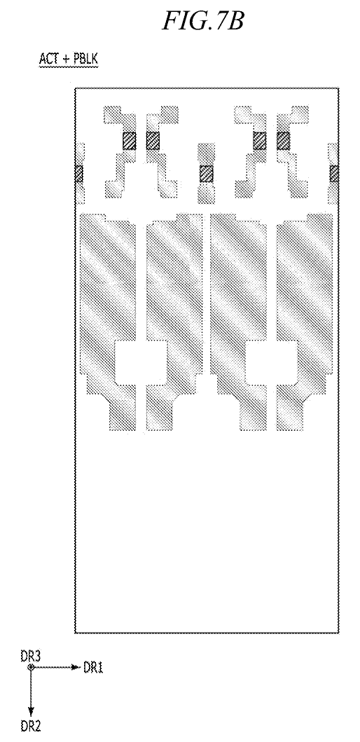

FIG. 7A is a plan view of a doping mask pattern PBLK according to one or more embodiments.

FIG. 7B is an exemplary illustration in which the shape shown in FIG. 7A is superimposed on FIG. 6.

In FIG. 7B, the portion corresponding to FIG. 7A is illustrated with a darker shading than the portion corresponding to FIG. 6, but this merely is for convenience of descriptions, and a shape and a shading (or color) of the doping mask pattern PBLK is not limited thereto.

Referring to FIG. 7A and FIG. 7B, the doping mask pattern PBLK is for selective doping of the lower semiconductor pattern ACT. Particularly, during a doping process, a region of the lower semiconductor pattern ACT that does not overlap with the doping mask pattern PBLK may be doped, and a region of the lower semiconductor pattern ACT that overlaps with the doping mask pattern PBLK may not be doped. The doping mask pattern PBLK may be removed after a doping process.

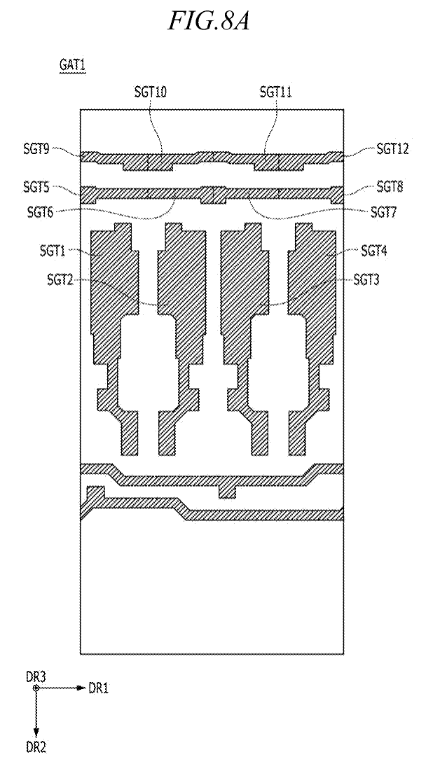

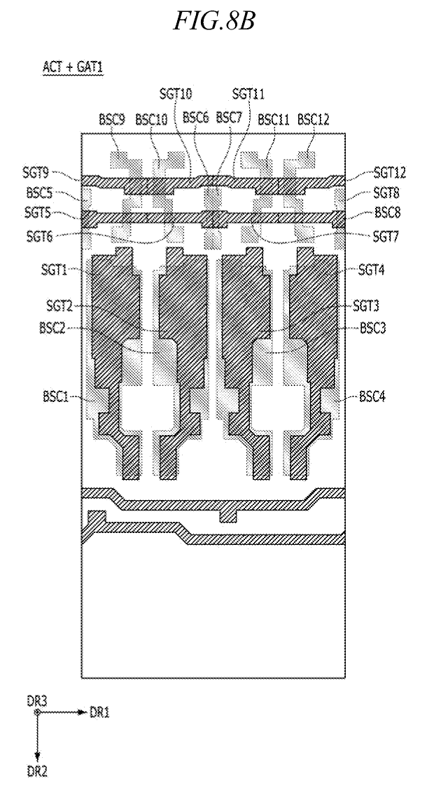

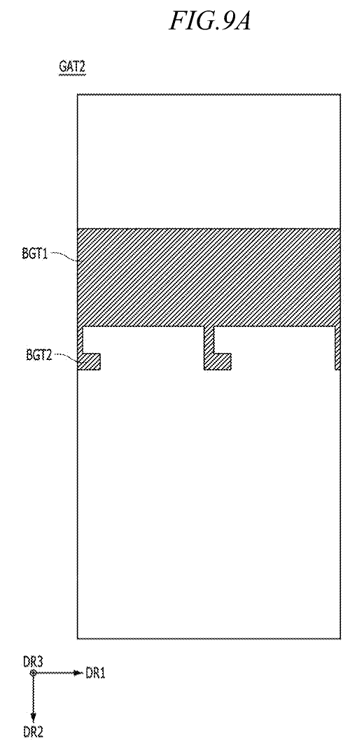

FIG. 8A is a plan view of a sub gate pattern GAT1 according to one or more embodiments.

FIG. 8B is an exemplary illustration in which the shape shown in FIG. 8A is superimposed on FIG. 6.

In FIG. 8B, the portion corresponding to FIG. 8A is illustrated with a darker shading than the portion corresponding to FIG. 6, but this merely is for convenience of descriptions, and a shape and a shading (or color) of the sub gate pattern GAT1 is not limited thereto.

Referring to FIG. 8A, the sub gate pattern GAT1 may include a first sub gate unit (i.e., portion) through a twelfth sub gate unit SGT1~SGT12.

The first sub gate unit through the twelfth sub gate unit SGT1~SGT12 may overlap with the first lower semiconductor unit through the twelfth lower semiconductor unit BSC1~BSC12, respectively.

The first sub gate unit through the fourth sub gate unit SGT1~SGT4 may be spaced apart from one another and disposed sequentially along the first direction DR1. That is, the second sub gate unit SGT2 may be disposed between the first sub gate unit SGT1 and the third sub gate unit SGT3, and the third sub gate unit SGT3 may be disposed between the second sub gate unit SGT2 and the fourth sub gate unit SGT4. In one or more embodiments, a shape of the first sub gate unit SGT1 may be same as a shape of the third sub gate unit SGT3, and a shape of the second sub gate unit SGT2 may be same as a shape of the fourth sub gate unit SGT4.

The fifth sub gate unit through the eighth sub gate unit SGT5~SGT8 may be sequentially disposed along the first direction DR1. That is, the sixth sub gate unit SGT6 may be disposed between the fifth sub gate unit SGT5 and the seventh sub gate unit SGT7, and the seventh sub gate unit SGT7 may be disposed between the sixth sub gate unit SGT6 and the eight sub gate unit SGT8. In one or more embodiments, a shape of the fifth sub gate unit SGT5 may be same as a shape of the seventh sub gate unit SGT7, and a shape of the sixth sub gate unit SGT6 may be same as a shape of the eighth sub gate unit SGT8.

The sixth sub gate unit SGT6 may extend from the fifth sub gate unit SGT5, the seventh sub gate unit SGT7 may extend from the sixth sub gate unit SGT6, and the eighth sub gate unit SGT8 may extend from the seventh sub gate unit SGT7.

In one or more embodiments, the fifth gate signal GS5 may be provided to the fifth sub gate unit through the eighth sub gate unit SGT5~SGT8, and the sixth gate signal GS6 may be provided to the ninth sub gate unit through the twelfth sub gate unit SGT9~SGT12.

The ninth sub gate unit through the twelfth sub gate unit SGT9~SGT12 may be sequentially disposed along the first direction DR1. That is, the tenth sub gate unit SGT10 may be disposed between the ninth sub gate unit SGT9 and the eleventh sub gate unit SGT11, and the eleventh sub gate unit SGT11 may be disposed between the tenth sub gate unit SGT10 and the twelfth sub gate unit SGT12. In one or more embodiments, a shape of the ninth sub gate unit SGT9 may be same as a shape of the eleventh sub gate unit SGT11, and a shape of the tenth sub gate unit SGT10 may be same as a shape of the twelfth sub gate unit SGT12.

The tenth sub gate unit SGT10 may extend from the ninth sub gate unit SGT9, the eleventh sub gate unit SGT11 may extend from the tenth sub gate unit SGT10, and the twelfth sub gate unit SGT12 may extend from the eleventh sub gate unit SGT11.

In one or more embodiments, the fifth lower semiconductor unit BCS5 may be a component of the first main light-emission control transistor TRE1, and a portion of the fifth sub gate unit SGT5 overlapping with the fifth lower semiconductor unit BCS5 may be a component of the control electrode of the first main light-emission control transistor TRE1.

In one or more embodiments, the sixth lower semiconductor unit BCS6 may be a component of the second main light-emission control transistor TRE2, and a portion of the sixth sub gate unit SGT6 overlapping with the sixth lower semiconductor unit BCS6 may be a component of the control electrode of the second main light-emission control transistor TRE2.

In one or more embodiments, the seventh lower semiconductor unit BCS7 may be a component of the third main light-emission control transistor TRE3, and a portion of the seventh sub gate unit SGT7 overlapping with the seventh lower semiconductor unit BCS7 may be a component of the control electrode of the third main light-emission control transistor TRE3.

In one or more embodiments, the eighth lower semiconductor unit BCS8 may be a component of the fourth main light-emission control transistor TRE4, and a portion of the eighth sub gate unit SGT8 overlapping with the eighth lower semiconductor unit BCS8 may be a component of the control electrode of the fourth main light-emission control transistor TRE4.

In one or more embodiments, the ninth lower semiconductor BCS9 may be a component of the first sub light-emission control transistor TRL1, and a portion of the ninth sub gate unit SGT9 overlapping with the ninth lower semiconductor unit BCS9 may be a components of the control electrode of the first sub light-emission control transistor TRL1.

In one or more embodiments, the tenth lower semiconductor unit BCS10 may be a component of the second sub light-emission control transistor TRL2, and a portion of the tenth sub gate unit SGT10 overlapping with the tenth lower semiconductor unit BCS10 may be a component of the control electrode of the second sub light-emission control transistor TRL2.

In one or more embodiments, the eleventh lower semiconductor unit BCS11 may be a component of the third sub light-emission control transistor TRL3, and a portion of the eleventh sub gate unit SGT11 overlapping with the eleventh lower semiconductor unit BCS11 may be a component of the control electrode of the third sub light-emission control transistor TRL3.

In one or more embodiments, the twelfth lower semiconductor unit BCS12 may be a component of the fourth sub light-emission control transistor TRL4, and a portion of the twelfth sub gate unit SGT12 overlapping with the twelfth lower semiconductor unit BCS12 may be a component of the control electrode of the fourth sub light-emission control transistor TRL4.

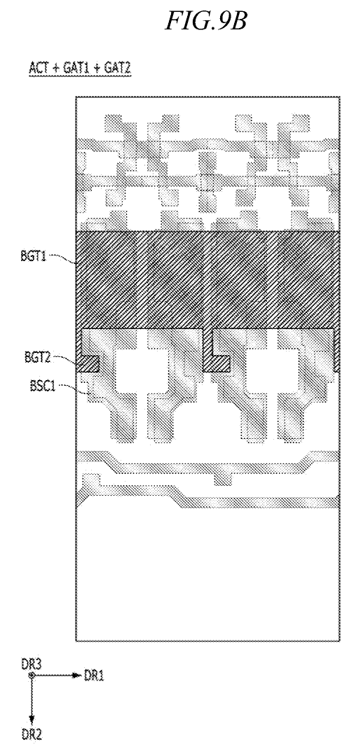

FIG. 9A is a plan view of a lower gate pattern GAT2 according to one or more embodiments.

FIG. 9B is an exemplary illustration in which the shape shown in FIG. 9A is superimposed on FIG. 8B.

In FIG. 9B, the portion corresponding to FIG. 9A is illustrated with a darker shading than the portion corresponding to FIG. 8B, but this merely is for convenience of descriptions, and a shape and a shading (or color) of the lower gate pattern GAT2 is not limited thereto.

Referring to FIG. 9A and FIG. 9B, the lower gate pattern GAT2 may include a first lower gate unit BGT1 and a second lower gate unit BGT2.

The first lower gate unit BGT1 may extend in the first direction DR1.

The second lower gate unit BGT2 may extend from the first lower gate unit BGT1 in the second direction DR2.

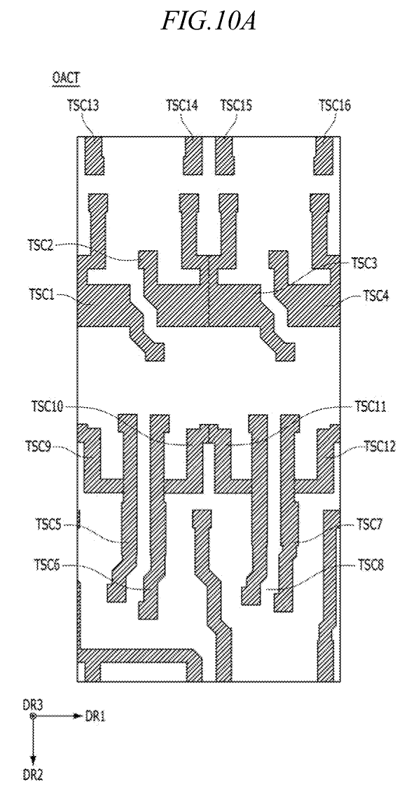

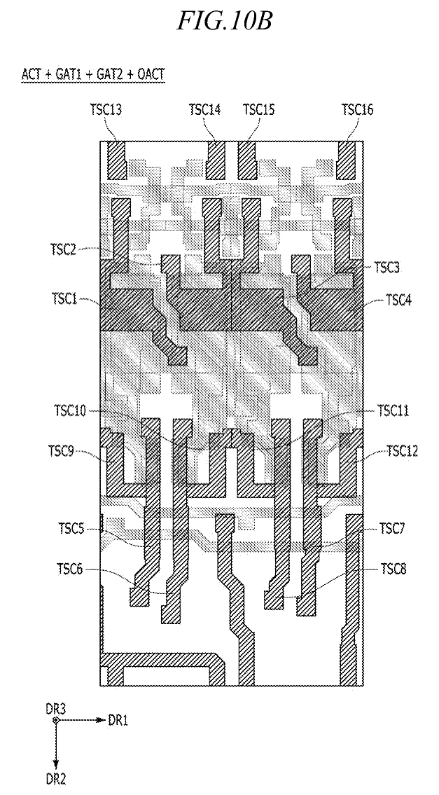

FIG. 10A is a plan view of an upper semiconductor pattern OACT according to one or more embodiments.

FIG. 10B is an exemplary illustration in which the shape shown in FIG. 10A is superimposed on FIG. 9B.

In FIG. 10B, the portion corresponding to FIG. 10A is illustrated with a darker shading than the portion corresponding to FIG. 9B, but this merely is for convenience of descriptions, and a shape and a shading (or color) of the upper semiconductor pattern OACT is not limited thereto.

Referring to FIG. 10A and FIG. 10B, the upper semiconductor pattern OACT may include a first upper semiconductor unit through a sixteenth upper semiconductor unit TSC1~TSC16.

The first upper semiconductor unit through the fourth upper semiconductor unit TSC1~TSC4 may be sequentially disposed along the first direction DR1. In one or more embodiments, a shape of the first upper semiconductor unit TSC1 may be same as a shape of the third upper semiconductor unit TSC3, and a shape of the second upper semiconductor unit TSC2 may be same as a shape of the fourth upper semiconductor unit TSC4.

The third upper semiconductor unit TSC3 may extend from the second upper semiconductor unit TSC2.

The fifth upper semiconductor unit through the eighth upper semiconductor unit TSC5~TSC8 may be spaced apart from the first upper semiconductor unit through the fourth upper semiconductor unit TSC1~TSC4, and sequentially disposed along the first direction DR1. In one or more embodiments, a shape of the fifth upper semiconductor unit TSC5 may be same as a shape of the seventh upper semiconductor unit TSC7, and a shape of the sixth upper semiconductor unit TSC6 may be same as a shape of the eighth upper semiconductor unit TSC8.

The ninth upper semiconductor unit through the twelfth upper semiconductor unit TSC9~TSC12 may be sequentially disposed along the first direction DR1. In one or more embodiments, a shape of the ninth upper semiconductor unit TSC9 may be same as a shape of the eleventh upper semiconductor unit TSC11, and a shape of the tenth upper semiconductor unit TSC10 may be same as a shape of the twelfth upper semiconductor unit TSC12.

The thirteenth upper semiconductor unit through the sixteenth upper semiconductor unit TSC13~TSC16 may be spaced apart from the first upper semiconductor unit through the twelfth upper semiconductor unit TSC1~TSC12 and sequentially disposed along the first direction DR1. The ninth upper semiconductor unit through the twelfth upper semiconductor unit TSC9~TSC12 may extend from the fifth upper semiconductor unit through the eighth upper semiconductor unit TSC5~TSC8, respectively. In one or more embodiments, a shape of the thirteenth upper semiconductor unit TSC13 may be same as a shape of the fifteenth upper semiconductor unit TSC15, and a shape of the fourteenth upper semiconductor unit TSC14 may be same as a shape of the sixteenth upper semiconductor unit TSC16.

In one or more embodiments, the first upper semiconductor unit through the sixteenth upper semiconductor unit TSC1~TSC16 may each be an oxide semiconductor. The oxide semiconductor may be at least any one of a metal oxide semiconductor, a crystalline oxide semiconductor, and an amorphous oxide semiconductor. For example, the oxide semiconductor may include at least any one of indium-tin oxide (ITO), indium-gallium-zinc oxide (IGZO), zinc oxide (ZnO), indium-zinc oxide (IZnO), zinc-indium oxide (ZIO), indium oxide (InO), titanium oxide (TiO), indium-zinc-tin oxide (IZTO), and zinc-tin oxide (ZTO).

In other embodiments, the first upper semiconductor unit through the sixteenth upper semiconductor unit TSC1~TSC16 may each include a silicon semiconductor. The silicon semiconductor may include at least any one of an amorphous silicon and a polycrystalline silicon. For example, the first upper semiconductor unit through the sixteenth upper semiconductor unit TSC1~TSC16 may each include LTPS (Low-Temperature Polycrystalline Silicon). However, the first upper semiconductor unit through the sixteenth upper semiconductor unit TSC1~TSC16 is not limited thereto, and the first upper semiconductor unit through the sixteenth upper semiconductor unit TSC1~TSC16 may be formed of various combinations of an oxide semiconductor and a silicon semiconductor.

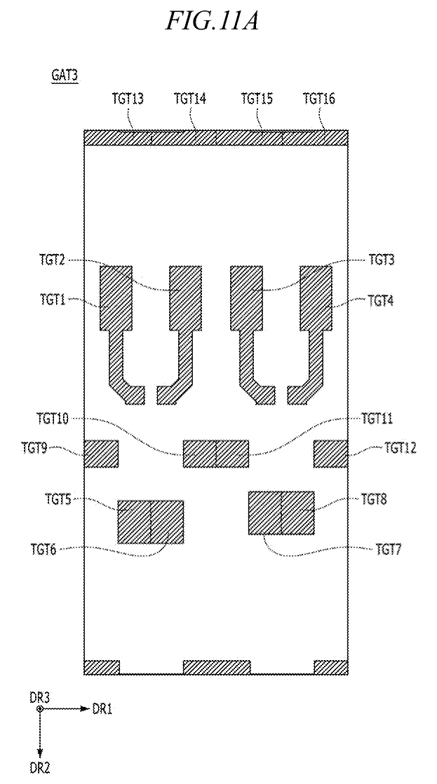

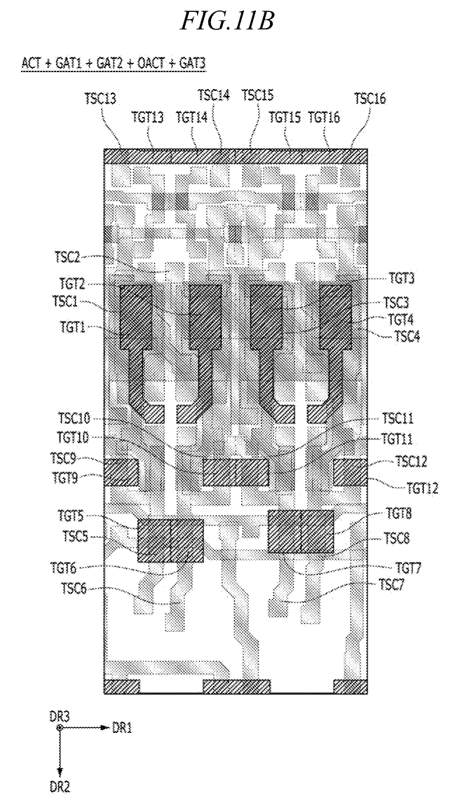

FIG. 11A is a plan view of an upper gate pattern GAT3 according to one or more embodiments.

FIG. 11B is an exemplary illustration in which the shape shown in FIG. 11A is superimposed on FIG. 10B.

In FIG. 11B, the portion corresponding to FIG. 11A is illustrated with a darker shading than the portion corresponding to FIG. 10B, but this merely is for convenience of descriptions, and a shape and a shading (or color) of the upper gate pattern GAT3 is not limited thereto.

Referring to FIG. 11A, the upper gate pattern GAT3 may include a first upper gate unit through a sixteenth upper gate unit TGT1~TGT16.

The first upper gate unit through the sixteenth upper gate unit TGT1~TGT16 may overlap with the first upper semiconductor unit through the sixteenth upper semiconductor unit TSC1~TSC16, respectively.

The first upper gate unit through the fourth upper gate unit TGT1~TGT4 may be spaced apart from one another and sequentially disposed along the first direction DR1. In one or more embodiments, a shape of the first upper gate unit TGT1 may be same as a shape of the third upper gate unit TGT3, and a shape of the second upper gate unit TGT2 may be same as a shape of the fourth upper gate unit TGT4.

In one or more embodiments, the first lower semiconductor unit BSC1 may be a component of the first driving transistor TRD1, and a portion of the first sub gate unit SGT1 overlapping with the first lower semiconductor unit BSC1 may be a component of the control electrode of the first driving transistor TRD1. In other embodiments, the first upper semiconductor unit TSC1 may be a component of the first driving transistor TRD1, and a portion of the first upper gate unit TGT1 overlapping with the first upper semiconductor unit TSC1 may be a component of the control electrode of the first driving transistor TRD1.

In one or more embodiments, the second lower semiconductor unit BSC2 may be a component of the second driving transistor TRD2, and a portion of the second sub gate unit SGT2 overlapping with the second lower semiconductor unit BSC2 may be a component of the control electrode of the second driving transistor TRD2. In other embodiments, the second upper semiconductor unit TSC2 may be a component of the second driving transistor TRD2, and a portion of the second upper gate unit TGT2 overlapping with the second upper semiconductor unit TSC2 may be a component of the control electrode of the second driving transistor TRD2.

In one or more embodiments, the third lower semiconductor unit BSC3 may be a component of the third driving transistor TRD3, and a portion of the third sub gate unit SGT3 overlapping with the third lower semiconductor unit BSC3 may be a component of the control electrode of the third driving transistor TRD3. In other embodiments, the third upper semiconductor unit TSC3 may be a component of the third driving transistor TRD3, and a portion of the third upper gate unit TGT3 overlapping with the third upper semiconductor unit TSC3 may be a component of the control electrode of the third driving transistor TRD3.

In one or more embodiments, the fourth lower semiconductor unit BSC4 may be a component of the fourth driving transistor TRD4, and a portion of the fourth sub gate unit SGT4 overlapping with the fourth lower semiconductor unit BSC4 may be a component of the control electrode of the fourth driving transistor TRD4. In other embodiments, the fourth upper semiconductor unit TSC4 may be a component of the fourth driving transistor TRD4, and a portion of the fourth upper gate unit TGT4 overlapping with the fourth upper semiconductor unit TSC4 may be a component of the control electrode of the fourth driving transistor TRD4.

The fifth upper gate unit through the eighth upper gate unit TGT5~TGT8 may be sequentially disposed along the first direction DR1. In one or more embodiments, a shape of the fifth upper gate unit TGT5 may be same as a shape of the seventh upper gate unit TGT7, and a shape of the sixth upper gate unit TGT6 may be same as a shape of the eighth upper gate unit TGT8.

In one or more embodiments, the fifth upper semiconductor unit TCS5 may be a component of the first switching transistor TRS1, and a portion of the fifth upper gate unit TGT5 overlapping with the fifth upper semiconductor unit TCS5 may be a component of the control electrode of the first switching transistor TRS1.

In one or more embodiments, the sixth upper semiconductor unit TCS6 may be a component of the second switching transistor TRS2, and a portion of the sixth upper gate unit TGT6 overlapping with the sixth upper semiconductor unit TCS6 may be a component of the control electrode of the second switching transistor TRS2.

In one or more embodiments, the seventh upper semiconductor unit TCS7 may be a component of the third switching transistor TRS3, and a portion of the seventh upper gate unit TGT7 overlapping with the seventh upper semiconductor unit TCS7 may be a component of the control electrode of the third switching transistor TRS3.

In one or more embodiments, the eighth upper semiconductor unit TCS8 may be a component of the fourth switching transistor TRS4, and a portion of the eight upper gate unit TGT8 overlapping with the eighth upper semiconductor unit TCS8 may be a component of the control electrode of the fourth switching transistor TRS4.

The ninth upper gate unit through the twelfth upper gate unit TGT9~TGT12 may be sequentially disposed along the first direction DR1. In one or more embodiments, a shape of the ninth upper gate unit TGT9 may be same as a shape of the eleventh upper gate unit TGT11, and a shape of the tenth upper gate unit TGT10 may be same as a shape of the twelfth upper gate unit TGT12.

In one or more embodiments, the ninth upper semiconductor unit TCS9 may be a component of the first compensation transistor TRC1, and a portion of the ninth upper gate unit TGT9 overlapping with the ninth upper semiconductor unit TCS9 may be a component of the control electrode of the first compensation transistor TRC1.

In one or more embodiments, the tenth upper semiconductor unit TCS10 may be a component of the second compensation transistor TRC2, and a portion of the tenth upper gate unit TGT10 overlapping with the tenth upper semiconductor unit TCS10 may be a component of the control electrode of the second compensation transistor TRC2.

In one or more embodiments, the eleventh upper semiconductor unit TCS11 may be a component of the third compensation transistor TRC3, and a portion of the eleventh upper gate unit TGT11 overlapping with the eleventh upper semiconductor unit TCS11 may be a component of the control electrode of the third compensation transistor TRC3.

In one or more embodiments, the twelfth upper semiconductor unit TCS12 may be a component of the fourth compensation transistor TRC4, and a portion of the twelfth upper gate unit TGT12 overlapping with the twelfth upper semiconductor unit TCS12 may be a component of the control electrode of the fourth compensation transistor TRC4.

The thirteenth upper gate unit through the sixteenth upper gate unit TGT13~TGT16 may be sequentially disposed along the first direction DR1. In one or more embodiments, a shape of the thirteenth upper gate unit TGT13 may be same as a shape of the fifteenth upper gate unit TGT15, and a shape of the fourteenth upper gate unit TGT14 may be same as a shape of the sixteenth upper gate unit TGT16.

The fourteenth upper gate unit TGT14 may extend from the thirteenth upper gate unit TGT13, the fifteenth upper gate unit TGT15 may extend from the fourteenth upper gate unit TGT14, and the sixteenth upper gate unit TGT16 may extend from the fifteenth upper gate unit TGT15.

The fourth gate signal GS4 may be provided to the thirteenth upper gate unit through the sixteenth upper gate unit TGT13~TG16, respectively.

In one or more embodiments, the thirteenth upper semiconductor unit TCS13 may be a component of the first initialization transistor TRI1, and a portion of the thirteenth upper gate unit TGT13 overlapping with the thirteenth upper semiconductor unit TCS13 may be a component of the control electrode of the first initialization transistor TRI1.

In one or more embodiments, the fourteenth upper semiconductor unit TCS14 may be a component of the second initialization transistor TRI2, and a portion of the fourteenth upper gate unit TGT14 overlapping with the fourteenth upper semiconductor unit TCS14 may be a component of the control electrode of the second initialization transistor TRI2.

In one or more embodiments, the fifteenth upper semiconductor unit TCS15 may be a component of the third initialization transistor TRI3, and a portion of the fifteenth upper gate unit TGT15 overlapping with the fifteenth upper semiconductor unit TCS15 may be a component of the control electrode of the third initialization transistor TRI3.

In one or more embodiments, the sixteenth upper semiconductor unit TCS16 may be a component of the fourth initialization transistor TRI4, and a portion of the sixteenth upper gate unit TGT16 overlapping with the sixteenth upper semiconductor unit TCS16 may be a component of the control electrode of the fourth initialization transistor TRI4.

In one or more embodiments, a first compensation capacitor CST1 may be defined between any two of the first sub gate unit SGT1, the first lower gate unit BGT1, the first upper gate unit TGT1, and a first lower conductive unit (i.e., portion) BCP1.

In one or more embodiments, a second compensation capacitor CST2 may be defined between any two of the second sub gate unit SGT2, the second lower gate unit BGT2, the second upper gate unit TGT2, and the second lower conductive unit BCP2.

In one or more embodiments, a third compensation capacitor CST3 may be defined between any two of the third sub gate unit SGT3, the third lower gate unit BGT3, the third upper gate unit TGT3, and the third lower conductive unit BCP3.

In one or more embodiments, a fourth compensation capacitor CST4 may be defined between any two of the fourth sub gate unit SGT4, and the fourth lower gate unit BGT4, and the fourth upper gate unit TGT4, and the fourth lower conductive unit BCP4.

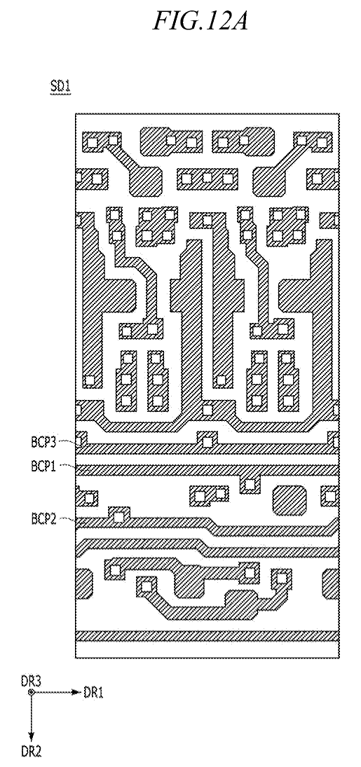

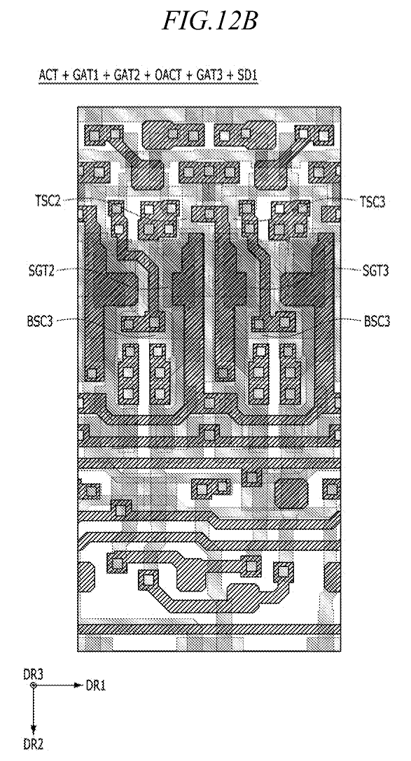

FIG. 12A is a plan view of a lower conductive pattern SD1 according to one or more embodiments.

FIG. 12B is an exemplary illustration in which the shape shown in FIG. 11A is superimposed on FIG. 10B.

In FIG. 12B, the portion corresponding to FIG. 12A is illustrated with a darker shading than the portion corresponding to FIG. 10B, but this merely is for convenience of descriptions, and a shape and a shading (or color) of the lower conductive pattern SD1 is not limited thereto.

The lower conductive pattern SD1 may include a first lower conductive unit through a third lower conductive unit BCP1~BCP3.

The first lower conductive unit through the third lower conductive unit BCP1~BCP3 may be spaced apart from one another. The first lower conductive unit through the third lower conductive unit BCP1~BCP3 may each extend in a first direction.

The first lower conductive part BCP1 may be configured to provide a first gate signal GS1 to the fifth upper gate unit TGT5 and the seventh upper gate unit TGT7, respectively. That is, the first lower conductive unit BCP1 may be configured to provide a first gate signal GS1 to the respective control electrode of the first switching transistor TRS1 and the third switching transistor TRS3.

The second lower conductive unit BCP2may be configured to provide a second gate signal GS2 to the sixth upper gate unit TGT6 and the eighth upper gate unit TGT8, respectively. That is, the second lower conductive unit BCP2 may be configured to provide a second gate signal GS2 to the respective control electrode of the second switching transistor TRS2 and the fourth switching transistor TRS4.

The third lower conductive unit BCP3 may be configured to provide a third gate signal GS3 to the ninth upper gate unit through the twelfth upper gate unit TGT9~TGT12, respectively. That is, the third lower conductive unit BCP3 may be configured to provide a third gate signal GS3 to the respective control electrode of the first compensation transistor through the fourth compensation transistor TRC1~TRC4.

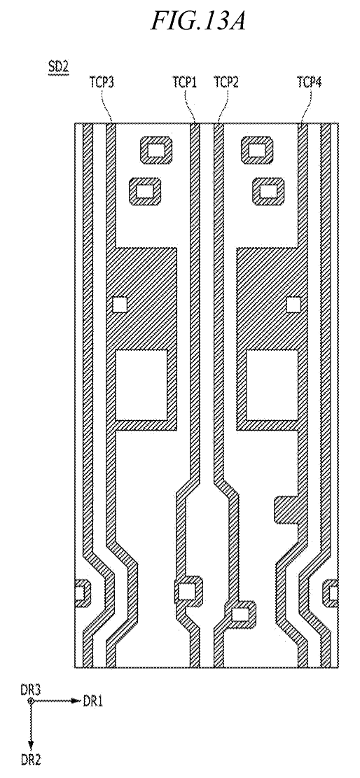

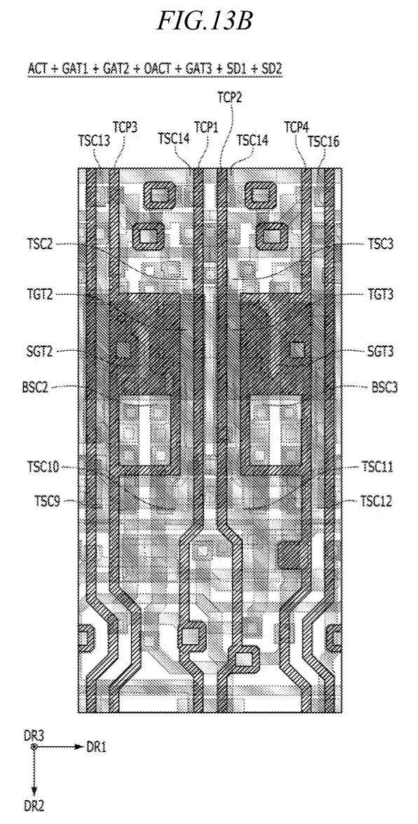

FIG. 13A is a plan view of an upper conductive pattern SD2 according to one or more embodiments.

FIG. 13B is an exemplary illustration in which the shape shown in FIG. 13A is superimposed on FIG. 12B.

The upper conductive pattern SD2 may be disposed above the upper gate pattern GAT3.

Referring to FIG. 13A, the upper conductive pattern SD2 may include a first upper conductive unit through a fourth upper conductive unit TCP1~TCP4.

The first upper conductive unit through the fourth upper conductive unit TCP1~TCP4 may each extend in the second direction DR2. In one or more embodiments, a shape of the first upper conductive unit TCP1 may be same as a shape of the third upper conductive unit TCP3, and a shape of the second upper conductive unit TCP2 may be same as a shape of the fourth upper conductive unit TCP4.

The first upper conductive unit TCP1 may overlap with at least any one of the second lower semiconductor unit BSC2, the second sub gate unit SGT2, the second upper semiconductor unit TSC2, and the second upper gate unit TGT2. The first upper conductive unit TCP1 may be electrically connected to the first light-emitting diode LD1 and the third light-emitting diode LD3.

In one or more embodiments, the first upper conductive unit TCP1 may be configured to provide a first data signal DS1 to the first sub gate unit SGT1 and the third sub gate unit SGT3. In other embodiments, the first upper conductive unit TCP1 may be configured to provide a first data signal DS1 to the first upper gate unit TGT1 and the third upper gate unit TGT3.

In one or more embodiments, the first upper conductive unit TCP1 may be electrically connected to the fifth upper semiconductor unit TSC5 and the seventh upper semiconductor unit TSC7. That is, the first upper conductive unit TCP1 may be electrically connected to the respective input electrode or output electrode of the first switching transistor TRS1 and the third switching transistor TRS3.

The second upper conductive unit TCP2 may overlap with at least any one of the third lower conductive unit BSC3, the third sub gate unit SGT3, the third upper semiconductor unit TSC3, and the third upper gate unit TGT3. The second upper conductive unit TCP2 may be electrically connected to the second light-emitting diode LD2 and the fourth light-emitting diode LD4.

The second upper conductive unit TCP2 may be configured to provide a second data signal DS2 to the second sub gate unit SGT2 and the fourth sub gate unit SGT4, or to the second upper gate unit TGT2 and the fourth upper gate unit TGT4.

The third upper conductive unit TCP3 may be configured to provide an initialization signal VINT or a reference voltage signal VREF.

The third upper conductive unit TCP3 may be electrically connected to the ninth upper semiconductor unit through the twelfth upper semiconductor unit TSC9~TSC12, or to the thirteenth upper semiconductor unit through the sixteenth upper semiconductor unit TSC13~TSC16.

The fourth upper conductive unit TCP4 may be configured to provide a first power signal ELVDD.

The fourth upper conductive unit TCP4 may be electrically connected respectively to the fifth lower semiconductor unit through the eighth lower semiconductor unit BSC5~BSC8 of the lower semiconductor pattern ACT.

The first upper conductive unit TCP1 and the second upper conductive unit TCP2 may be disposed between the third upper conductive unit TCP3 and the fourth upper conductive unit TCP4.

In one or more embodiments, the lower conductive pattern SD1 and the upper conductive pattern SD2 may each make contact with at least any one of the lower semiconductor pattern ACT, the sub gate pattern GAT1, the lower gate pattern GAT2, the upper semiconductor pattern OACT, and the upper gate pattern GAT3.

An example of the above will be described in detail. However, connection relationships between the lower conductive pattern SD1 and the upper conductive pattern SD2, and the lower semiconductor pattern ACT, the sub gate pattern GAT1, the lower gate pattern GAT2, the upper semiconductor pattern OACT, and the upper gate pattern GAT3 are not limited to the example provided below.

In one or more embodiments, the fifth upper semiconductor unit TSC5 and the seventh upper semiconductor unit TSC7 may each be electrically connected to the first sub gate unit SGT1 and the third sub gate unit SGT3. In other embodiments, the fifth upper semiconductor unit TSC5 and the seventh upper semiconductor unit TSC7 may each be electrically connected to the first upper gate unit TGT1 and the third upper gate unit TGT3. That is, an input electrode or output electrode of the first switching transistor TRS1 may be electrically connected to the control electrode of the first driving transistor TRD1, and an input electrode or output electrode of the third switching transistor TRS3 may be electrically connected to the third driving transistor TRD3.

Accordingly, when the first switching transistor TRS1 is turned on, the first upper conductive unit TCP1 may provide at least a portion of the first data signal DS1 to the control electrode of the first driving transistor TRD1, and when the third switching transistor TRS3 is turned on, the first upper conductive unit TCP1 may provide at least a portion of the first data signal DS1 to the control electrode of the third driving transistor TRD3.

In one or more embodiments, the second upper conductive unit TCP2 may be electrically connected to the sixth upper semiconductor unit TSC6 and the eighth upper semiconductor unit TSC8. That is, the second upper conductive unit TCP2 may be electrically connected to an input electrode or output electrode of the second switching transistor TRS2 and the fourth switching transistor TRS4, respectively.

In one or more embodiments, the sixth upper semiconductor unit TSC6 and the eighth upper semiconductor unit TSC8 may each be electrically connected to the second sub gate unit SGT2 and the fourth sub gate unit SGT4. In other embodiments, the sixth upper semiconductor unit TSC6 and the eighth upper semiconductor unit TSC8 may each be electrically connected to the second upper gate unit TGT2 and the fourth upper gate unit TGT4. That is, the input electrode or output electrode of the second switching transistor TRS2 may be electrically connected to the control electrode of the second driving transistor TRD2, and the input electrode or output electrode of the fourth switching transistor TRS4 may be electrically connected to the control electrode of the fourth driving transistor TRD4.

Therefore, when the second switching transistor TRS2 is turned on, the second upper conductive unit TCP2 may be provide at least a portion of the second data signal DS2 to the control electrode of the second driving transistor TRD2, and when the fourth switching transistor TRS4 is turned on, the second upper conductive unit TCP2 may provide at least a portion of the second data signal DS2 to the control electrode of the fourth driving transistor TRD4.

The third upper conductive unit TCP3 may be configured to provide a reference voltage signal VREF or an initialization signal VINT.

In one or more embodiments, the third upper conductive unit TCP3 may be electrically connected to the ninth upper semiconductor unit through the twelfth upper semiconductor unit TSC9~TSC12, or the thirteenth upper semiconductor unit through h the sixteenth upper semiconductor unit TSC13~TSC16. That is, the third upper conductive unit TCP3 may provide a reference voltage signal VREF to an input electrode or output electrode of the first compensation transistor through the fourth compensation transistor TRC1~TRC4, respectively, or an initialization signal VINT to an input electrode or output electrode of the first initialization transistor through the fourth initialization transistor TRI1~TRI4, respectively.

The fourth upper conductive unit TCP4 may be configured to provide a first power signal ELVDD.

In one or more embodiments, the fourth upper conductive unit TCP4 may be electrically connected to the fifth lower semiconductor unit through the eighth lower semiconductor unit BSC5~BSC8, respectively, of the lower semiconductor pattern ACT. That is, the fourth upper conductive unit TCP4 may provide a first power signal ELVDD to an input electrode or output electrode of the first main light-emission control transistor through the fourth main light-emission control transistor TRE1~TRE4, respectively.

While aspects of embodiments have been particularly shown and described, it will be understood that various changes in form and details may be made therein without departing from the spirit and scope of the following claims.

What is claimed is:

1. A display panel comprising:
a first pixel configured to emit first light;
a second pixel configured to emit second light;
a third pixel configured to emit third light;
a fourth pixel configured to emit fourth light;
a first data line configured to provide a first data signal to the first pixel and the third pixel, respectively; and
a second data line configured to provide a second data signal to the second pixel and the fourth pixel, respectively,
wherein a wavelength of the second light is greater than a wavelength of the third light and smaller than a wavelength of the first light, and a wavelength of the fourth light is greater than the wavelength of the third light and smaller than the wavelength of the first light, and
wherein the first pixel or the third pixel is between the second pixel and the fourth pixel.

2. The display panel of claim 1, wherein the first pixel comprises a first pixel circuit and a first light-emitting diode,
wherein the second pixel comprises a second pixel circuit and a second light-emitting diode,
wherein the third pixel comprises a third pixel circuit and a third light-emitting diode,
wherein the fourth pixel comprises a fourth pixel circuit and a fourth light-emitting diode,
wherein the first data line has at least a portion overlapping with the second pixel circuit, and
wherein the second data line has at least a portion overlapping with the third pixel circuit.

3. The display panel of claim 2, wherein the first pixel circuit comprises:
a first driving transistor connected to the first light-emitting diode; and
a first switching transistor between the first data line and a control electrode of the first driving transistor,
wherein the second pixel circuit comprises:
a second driving transistor connected to the second light-emitting diode; and
a second switching transistor between the second data line and a control electrode of the second driving transistor,
wherein the third pixel circuit comprises:
a third driving transistor connected to the third light-emitting diode; and
a third switching transistor between the first data line and a control electrode of the third driving transistor,
wherein the fourth pixel circuit comprises:
a fourth driving transistor connected to the fourth light-emitting diode; and
a fourth switching transistor between the second data line and a control electrode of the fourth driving transistor,
wherein the first switching transistor and the third switching transistor are controlled by a first gate signal, and
wherein the second switching transistor and the fourth switching transistor are controlled by a second gate signal.

4. The display panel of claim 3, further comprising:
a first gate line configured to provide the first gate signal; and
a second gate line configured to provide the second gate signal.

5. The display panel of claim 3, further comprising a reference voltage line configured to provide a reference voltage signal,
wherein the first pixel circuit further comprises a first compensation transistor between the reference voltage line and the control electrode of the first driving transistor,
wherein the second pixel circuit further comprises a second compensation transistor between the reference voltage line and the control electrode of the second driving transistor,
wherein the third pixel circuit further comprises a third compensation transistor between the reference voltage line and the control electrode of the third driving transistor, and
wherein the fourth pixel circuit further comprises a fourth compensation transistor between the reference voltage line and the control electrode of the fourth driving transistor.

6. The display panel of claim 5, further comprising a third gate line configured to provide a third gate signal,
wherein each of the first compensation transistor through the fourth compensation transistor is controlled by the third gate signal.

7. The display panel of claim 2, further comprising an initialization line configured to provide an initialization signal,
wherein the first pixel circuit further comprises a first initialization transistor between the initialization line and the first light-emitting diode,
wherein the second pixel circuit further comprises a second initialization transistor between the initialization line and the second light-emitting diode,
wherein the third pixel circuit further comprises a third initialization transistor between the initialization line and the third light-emitting diode, and
wherein the fourth pixel circuit further comprises a fourth initialization transistor between the initialization line and the fourth light-emitting diode.

8. The display panel of claim 7, further comprising a fourth gate line configured to provide a fourth gate signal,
wherein each of the first initialization transistor through the fourth initialization transistor is controlled by the fourth gate signal.

9. The display panel of claim 3, further comprising a first power line configured to provide a first power signal,
wherein the first pixel circuit further comprises a first main light-emission control transistor between the first power line and the first driving transistor,
wherein the second pixel circuit further comprises a second main light-emission control transistor between the first power line and the second driving transistor,
wherein the third pixel circuit further comprises a third main light-emission control transistor between the first power line and the third driving transistor, and
wherein the fourth pixel circuit further comprises a fourth main light-emission control transistor between the first power line and the fourth driving transistor.

10. The display panel of claim 9, further comprising a fifth gate line configured to provide a fifth gate signal,
wherein each of the first main light-emission control transistor through the fourth main light-emission control transistor is controlled by the fifth gate signal.

11. The display panel of claim 3, wherein the first pixel circuit further comprises a first sub light-emission control transistor between the first driving transistor and the first light-emitting diode,
wherein the second pixel circuit further comprises a second sub light-emission control transistor between the second driving transistor and the second light-emitting diode,
wherein the third pixel circuit further comprises a third sub light-emission control transistor between the third driving transistor and the third light-emitting diode, and
wherein the fourth pixel circuit further comprises a fourth sub light-emission control transistor between the fourth driving transistor and the fourth light-emitting diode.

12. The display panel of claim 11, further comprising a sixth gate line configured to provide a sixth gate signal,
wherein the first sub light-emission control transistor through the fourth sub light-emission control transistor are controlled by the sixth gate signal.

13. The display panel of claim 11, further comprising a second power line configured to provide a second power signal,
wherein the second power line is connected to each of the first light-emitting diode through the fourth light-emitting diode.

14. An electronic device comprising:
a semiconductor pattern comprising a lower semiconductor pattern and an upper semiconductor pattern on different layers,
wherein the lower semiconductor pattern comprises a first lower semiconductor portion through a fourth lower semiconductor portion spaced apart from one another and sequentially provided along a first direction,
wherein the upper semiconductor pattern comprises a first upper semiconductor portion through a fourth upper semiconductor portion sequentially provided along the first direction, and
wherein the third upper semiconductor portion extends from the second upper semiconductor portion;
a gate pattern comprising a sub gate pattern and an upper gate pattern,
wherein the sub gate pattern comprises a first sub gate portion through a fourth sub gate portion overlapping with the first lower semiconductor portion through the fourth lower semiconductor portion, respectively, and
wherein the upper gate pattern is above the upper semiconductor pattern and comprises a first upper gate portion through a fourth upper gate portion overlapping with the first upper semiconductor portion through the fourth upper semiconductor portion, respectively; and
an upper conductive pattern above the upper gate pattern and comprising a first upper conductive portion and a second upper conductive portion, each of the first upper conductive portion and the second upper conductive portion extending in a second direction intersecting with the first direction,
wherein the first upper conductive portion overlaps with at least any one of the second lower semiconductor portion, the second sub gate portion, the second upper semiconductor portion, and the second upper gate portion, and
wherein the second upper conductive portion overlaps with at least any one of the third lower semiconductor portion, the third sub gate portion, the third upper semiconductor portion, and the third upper gate portion,
wherein the first upper conductive portion is configured to provide a first data signal to the first sub gate portion and the third sub gate portion, or to the first upper gate portion and the third upper gate portion, and
wherein the second upper conductive portion is configured to provide a second data signal to the second sub gate portion and the fourth sub gate portion, or to the second upper gate portion and the fourth upper gate portion.

15. The electronic device of claim 14, further comprising a lower conductive pattern between the upper gate pattern and the upper conductive pattern, the lower conductive pattern comprising a first lower conductive portion and a second lower conductive portion spaced apart from each other,
wherein the upper semiconductor pattern further comprises a fifth upper semiconductor portion through an eighth upper semiconductor portion spaced apart from the first upper semiconductor portion through the fourth upper semiconductor portion and sequentially provided along the first direction,
wherein the upper gate pattern further comprises a fifth upper gate portion through an eighth upper gate portion overlapping with the fifth upper semiconductor portion through the eighth upper semiconductor portion, respectively,
wherein the first lower conductive portion is configured to provide a first gate signal to the fifth upper gate portion and the seventh upper gate portion, respectively, and
wherein the second lower conductive portion is configured to provide a second gate signal to the sixth upper gate portion and the eighth upper gate portion, respectively.

16. The electronic device of claim 15, wherein the lower conductive pattern further comprises a third lower conductive portion,
wherein the upper semiconductor pattern further comprises a ninth upper semiconductor portion through a twelfth upper semiconductor portion extending from the fifth upper semiconductor portion through the eighth upper semiconductor portion, respectively,
wherein the upper gate pattern further comprises a ninth upper gate portion through a twelfth upper gate portion overlapping with the ninth upper semiconductor portion through the twelfth upper semiconductor portion, respectively, and
wherein the third lower conductive portion is configured to provide a third gate signal to the ninth upper gate portion through the eleventh upper gate portion, respectively.

17. The electronic device of claim 16, wherein the upper semiconductor pattern further comprises a thirteenth upper semiconductor portion through a sixteenth upper semiconductor portion spaced part from the first upper semiconductor portion through the twelfth upper semiconductor portion and sequentially provided along the first direction,
wherein the upper gate pattern further comprises a thirteenth upper gate portion through the sixteenth upper gate portion overlapping with the thirteenth upper semiconductor portion through the sixteenth upper semiconductor portion, respectively,
wherein the fourteenth upper gate portion extends from the thirteenth gate portion, the fifteenth upper gate portion extends from the fourteenth upper gate portion, and the sixteenth upper gate portion extends from the fifteenth upper gate portion, and
wherein the thirteenth upper gate portion through the sixteenth upper gate portion are respectively provided with a fourth gate signal.

18. The electronic device of claim 17, wherein the lower semiconductor pattern further comprises a fifth lower semiconductor portion through a twelfth lower semiconductor portion spaced apart from the first lower semiconductor portion through the fourth lower semiconductor portion,
wherein the sub gate pattern further comprises a fifth sub gate portion through a twelfth sub gate portion overlapping with the fifth lower semiconductor portion through the twelfth lower semiconductor portion,
wherein the fifth sub gate portion through the eighth sub gate portion are provided with a fifth gate signal, and
wherein the ninth sub gate portion through the twelfth sub gate portion are provided with a sixth gate signal.

19. The electronic device of claim 16, wherein the upper conductive pattern further comprises a third upper conductive portion configured to provide an initialization signal or a reference voltage signal, and a fourth upper conductive portion configured to provide a first power signal,
wherein the first upper conductive portion and the second upper conductive portion are between the third upper conductive portion and the fourth upper conductive portion,
wherein the third upper conductive portion is connected to the ninth upper semiconductor portion through the twelfth upper semiconductor portion or to the thirteenth upper semiconductor portion through the sixteenth upper semiconductor portion, and
wherein the fourth upper conductive portion is connected to the fifth lower semiconductor portion through the eighth lower semiconductor portion, respectively.

20. An electronic device comprising a display panel, the display panel comprising:
a first pixel configured to emit first light;
a second pixel configured to emit second light;
a third pixel configured to emit third light;
a fourth pixel configured to emit fourth light;
a first data line configured to provide a first data signal to the first pixel and the third pixel, respectively; and
a second data line configured to provide a second data signal to the second pixel and the fourth pixel, respectively,
wherein a wavelength of the second light is greater than a wavelength of the third light and smaller than a wavelength of the first light, and a wavelength of the fourth light is greater than the wavelength of the third light and smaller than the wavelength of the first light, and
wherein the first pixel or the third pixel is between the second pixel and the fourth pixel.
